(19) United States
(12) Patent Application Publication
(10) Pub. No.: US 2026/0242980 A1
(43) Pub. Date: Aug. 20, 2026

(54) METHOD OF PRODUCING GALLIUM ARSENIDE SINGLE CRYSTAL, METHOD OF PRODUCING GALLIUM ARSENIDE SINGLE CRYSTAL SUBSTRATE, GALLIUM ARSENIDE SINGLE CRYSTAL SUBSTRATE, AND GALLIUM ARSENIDE SINGLE CRYSTAL

(71) Applicant: Sumitomo Electric Industries, Ltd., Osaka (JP)

(72) Inventor: Kazuya SHIBATA, Hyogo (JP)

(73) Assignee: Sumitomo Electric Industries, Ltd., Osaka (JP)

(21) Appl. No.: 19/480,143

(22) PCT Filed: Oct. 4, 2023
(86) PCT No.: PCT/JP2023/036226

§ 371 Date: Oct. 30, 2025

(51) Int. Cl. C30B 29/42; C30B 15/08; C30B 15/10

(52) U.S. Cl. CPC C30B 29/42; C30B 15/08; C30B 15/10

(57) ABSTRACT

A method of producing a gallium arsenide single crystal includes growing the gallium arsenide single crystal from a seed crystal using a gallium arsenide single crystal production apparatus. A growth side surface of the seed crystal is a plane having an off angle of 4° or more and 20° or less with respect to a (100) plane of the gallium arsenide single crystal. The apparatus includes a crucible, a crucible holding base that holds the crucible. The crucible includes a seed crystal accommodation portion, an increased-diameter portion connected to the seed crystal accommodation portion, and a straight barrel portion connected to the increased-diameter portion. The crucible holding base holds the increased-diameter portion. The increased-diameter portion is constituted of an upper region and a lower region. The upper region is separated from the crucible holding base, and the lower region is in contact with the crucible holding base.

### TECHNICAL FIELD

The present disclosure relates to a method of producing a gallium arsenide single crystal, a method of producing a gallium arsenide single crystal substrate, the gallium arsenide single crystal substrate, and the gallium arsenide single crystal.

### BACKGROUND ART

WO 2006/106644 (PTL 1) discloses a gallium arsenide single crystal ingot (hereinafter, also referred to as “GaAs single crystal ingot”) doped with silicon (Si) and to be applied to a gallium arsenide single crystal substrate (hereinafter, also referred to as “GaAs single crystal substrate”). An average value of a dislocation density of the GaAs single crystal ingot is 50 cm⁻² or less, and a relation of C0.8/C0.1<2.0 is satisfied when C0.1 is defined as a carrier concentration at a portion having a solidification ratio of 0.1 and C0.8 is defined as a carrier concentration at a portion having a solidification ratio of 0.8. Further, PTL 1 discloses that the carrier concentration of the GaAs single crystal ingot is 1.0×10¹⁷ cm⁻³ or more and 1.0×10¹⁹ cm⁻³ or less. WO 2021/251349 (PTL 2) discloses a GaAs single crystal ingot in which an average value of a dislocation density is 500 cm⁻² or less, an atomic concentration of Si is 2.0×10¹⁷ cm⁻³ or more and 1.5×10¹⁹ cm⁻³ or less, and a carrier concentration is 5.5×10¹⁷ cm⁻³ or less.

Each of Japanese Patent Laying-Open No. 2011-148693 (PTL 3) and Japanese Patent Laying-Open No. 2011-148694 (PTL 4) discloses an n type GaAs single crystal substrate doped with Si. In the GaAs single crystal substrate, the average values of the dislocation densities in PTL 3 and PTL 4 are respectively 40 to 100 cm⁻² and 15 to 30 cm⁻², and the Si atomic concentrations in PTL 3 and PTL 4 are respectively 5.0×10¹⁶ cm³ or more and 5.0×10¹⁷ cm⁻³ or less and 5.0×10¹⁶ cm⁻³ or more and 5.0×10¹⁷ cm⁻³ or less. Each of Japanese National Patent Publication No. 2011-527280 (PTL 5) and Sasabe, et. al, “VGF Method Suitable for Mass Production of Semiconductor Lasers, Low Dislocation Density GaAs Wafer”, Hitachi Cable, Vol. 20, August, 2001, pp. 33 to 36 (NPL 1) discloses a measurement method in which squares each having a predetermined size are formed on a main surface and a dislocation density is determined by counting dislocations present in each of the squares.

### CITATION LIST

### Patent Literature

PTL 1: WO 2006/106644
PTL 2: WO 2021/251349
PTL 3: Japanese Patent Laying-Open No. 2011-148693
PTL 4: Japanese Patent Laying-Open No. 2011-148694
PTL 5: Japanese National Patent Publication No. 2011-527280

### Non Patent Literature

NPL 1: Sasabe, et. al., “VGF Method Suitable for Mass Production of Semiconductor Lasers, Low Dislocation Density GaAs Wafer”, Hitachi Cable, Vol. 20, August, 2001, pp. 33 to 36

### SUMMARY OF INVENTION

A method of producing a gallium arsenide single crystal according to the present disclosure is a method of producing a gallium arsenide single crystal having a columnar shape. The production method includes growing the gallium arsenide single crystal from a seed crystal using a gallium arsenide single crystal production apparatus. A growth side surface of the seed crystal is a plane having an off angle of 4° or more and 200 or less with respect to a (100) plane of the gallium arsenide single crystal. The gallium arsenide single crystal production apparatus includes a crucible having a portion having a cylindrical shape, a crucible holding base that holds the crucible, and a heating element that heats the crucible. The crucible includes a seed crystal accommodation portion, an increased-diameter portion connected to the seed crystal accommodation portion, and a straight barrel portion connected to the increased-diameter portion on a side opposite to the seed crystal accommodation portion side. The seed crystal accommodation portion has a cavity portion having a cylindrical shape, the cavity portion being opened on a side on which the seed crystal accommodation portion is connected to the increased-diameter portion, the cavity portion being provided with a bottom wall formed on a side opposite to the increased-diameter portion. The increased-diameter portion has a truncated conical shape having a diameter that is increased upward in an axial direction of the crucible, and is connected to the seed crystal accommodation portion on a small-diameter side of the increased-diameter portion. The straight barrel portion has a hollow cylindrical shape and is connected to a large-diameter side of the increased-diameter portion. The crucible holding base holds the increased-diameter portion. The increased-diameter portion is constituted of an upper region and a lower region. The upper region is separated from the crucible holding base, and the lower region is in contact with the crucible holding base.

### BRIEF DESCRIPTION OF DRAWINGS

FIG. 1 is a flowchart showing an example of each of a method of producing a gallium arsenide single crystal and a method of producing a gallium arsenide single crystal substrate according to the present embodiment.

FIG. 2 is a longitudinal cross sectional view schematically illustrating a gallium arsenide single crystal production apparatus used in a step of growing the gallium arsenide single crystal in the method of producing the gallium arsenide single crystal according to the present embodiment.

FIG. 3 is an enlarged view of a main part of FIG. 2.

FIG. 4 is an explanatory plan view illustrating a main surface of the gallium arsenide single crystal substrate according to the present embodiment and a measurement target location (measurement target region) for measuring a carrier concentration in the substrate.

FIG. 5 is an explanatory view illustrating a state in which an imaginary grid, in which squares each having each side of 2 mm are laid out on the main surface of the gallium arsenide single crystal substrate shown in FIG. 4 such that the largest number of the squares are arranged side by side without overlapping with each other, is set in order to determine a dislocation density in the main surface.

FIG. 6 is an explanatory view illustrating a Hall measurement sample produced using the gallium arsenide single crystal substrate shown in FIG. 4.

FIG. 7 is a perspective view schematically illustrating the gallium arsenide single crystal according to the present embodiment.

### DETAILED DESCRIPTION

### Problem to be Solved by the Present Disclosure

In recent years, as disclosed in each of PTL 1 to PTL 5 and NPL 1, research and development have been advanced to produce a GaAs single crystal having excellent crystallinity and obtain, from the GaAs single crystal, a GaAs single crystal substrate having a very small average value of dislocation density or the like in its main surface. This is because a semiconductor device can be obtained from the substrate with an excellent yield. However, when a GaAs single crystal substrate having a large diameter of about 8 inches and having a main surface having an off angle of 4° or more with respect to a (100) plane of the GaAs single crystal is obtained by the method disclosed in each of PTL 1 to PTL 5 and NPL 1, the average value of the dislocation density in the main surface of the GaAs single crystal substrate becomes large, with the result that the yield of the semiconductor device tends to be adversely affected. Therefore, a GaAs single crystal substrate having a large diameter and a very small average value of dislocation density or the like in its main surface having a relatively large off angle has not been realized yet, and has been desired to be developed.

In view of the above circumstance, it is an object of the present disclosure to provide a method of producing a gallium arsenide single crystal so as to obtain a gallium arsenide single crystal substrate having a large diameter and a very small average value of dislocation density or the like in its main surface having a relatively large off angle. Further, it is an object of the present disclosure to provide a method of producing the gallium arsenide single crystal substrate, the gallium arsenide single crystal substrate, and the gallium arsenide single crystal.

### Advantageous Effect of the Present Disclosure

According to the present disclosure, there is provided a method of producing a gallium arsenide single crystal so as to obtain a gallium arsenide single crystal substrate having a large diameter and a very small average value of dislocation density or the like in its main surface having a relatively large off angle. Further, there are provided a method of producing the gallium arsenide single crystal substrate, the gallium arsenide single crystal substrate, and the gallium arsenide single crystal.

### SUMMARY OF EMBODIMENTS

First, a summary of embodiments of the present disclosure will be described. In order to solve the above-described problem, the present inventor has conducted diligent study. The present inventor has paid attention to producing a GaAs single crystal having excellent crystallinity while controlling a thermal environment of a gallium arsenide single crystal production apparatus (hereinafter, also referred to as “GaAs single crystal production apparatus”) so as to attain a more uniform thermal distribution in a crystal grown in a crucible. Specifically, the GaAs single crystal production apparatus used in a step of growing a gallium arsenide single crystal has such a structure that an increased-diameter portion is divided into an upper region and a lower region, the upper region is separated from a crucible holding base, and the lower region is in contact with the crucible holding base. Thus, the thermal environment in the above step was controlled so as to satisfy a relation of q(A1)<q(A2), where q represents a heat flux in a direction from an inner portion of the crucible toward the crucible holding base, A1 represents the upper region, A2 represents the lower region, q(A1) represents an amount of the heat flux passing through the upper region, and q(A2) represents an amount of the heat flux passing through the lower region. As a result, the present inventor has found that occurrence of thermal fluctuation in the crystal that is being grown is suppressed to attain a uniform thermal distribution, with the result that thermal strain in the crystal can be as small as possible even in a large single crystal having a diameter of about 8 inches. Thus, the present inventor has arrived at a method of producing, using the GaAs single crystal as a material, a GaAs single crystal substrate having a large diameter and a very small average value of dislocation density or the like in its main surface having a relatively large off angle. Moreover, the present inventor also has arrived at a method of producing a GaAs single crystal so as to obtain the GaAs single crystal substrate, thereby completing the present disclosure.

Next, embodiments of the present disclosure will be listed and described.
[1] A method of producing a gallium arsenide single crystal according to one embodiment of the present disclosure is a method of producing a gallium arsenide single crystal having a columnar shape. The production method includes growing the gallium arsenide single crystal from a seed crystal using a gallium arsenide single crystal production apparatus. A growth side surface of the seed crystal is a plane having an off angle of 4° or more and 20° or less with respect to a (100) plane of the gallium arsenide single crystal. The gallium arsenide single crystal production apparatus includes a crucible having a portion having a cylindrical shape, a crucible holding base that holds the crucible, and a heating element that heats the crucible. The crucible includes a seed crystal accommodation portion, an increased-diameter portion connected to the seed crystal accommodation portion, and a straight barrel portion connected to the increased-diameter portion on a side opposite to the seed crystal accommodation portion side. The seed crystal accommodation portion has a cavity portion having a cylindrical shape, the cavity portion being opened on a side on which the seed crystal accommodation portion is connected to the increased-diameter portion, the cavity portion being provided with a bottom wall formed on a side opposite to the increased-diameter portion. The increased-diameter portion has a truncated conical shape having a diameter that is increased upward in an axial direction of the crucible, and is connected to the seed crystal accommodation portion on a small-diameter side of the increased-diameter portion. The straight barrel portion has a hollow cylindrical shape and is connected to a large-diameter side of the increased-diameter portion. The crucible holding base holds the increased-diameter portion. The increased-diameter portion is constituted of an upper region and a lower region. The upper region is separated from the crucible holding base, and the lower region is in contact with the crucible holding base.

According to the method of producing the gallium arsenide single crystal with such a feature, a gallium arsenide single crystal in which thermal strain in the crystal is very small can be obtained. Thus, the gallium arsenide single crystal obtained by the above-described production method is provided as a material for producing a gallium arsenide single crystal substrate having a large diameter and a very small average value of dislocation density or the like in its main surface having a relatively large off angle.
[2] When a surface area of the upper region is defined as S(A1) and a surface area of the lower region is defined as S(A2), the increased-diameter portion preferably satisfies the following Formula I:

$$0.2 \leq S ( A 2 ) / ( S ( A 1 ) + S ( A 2 ) ) \leq 0.6 . \qquad Formula I$$

In this case, the gallium arsenide single crystal having the above-described feature can be readily obtained.
[3] Preferably, the upper region faces the crucible holding base in a direction perpendicular to a growth direction of the gallium arsenide single crystal. In this case, the gallium arsenide single crystal having the above-described feature can be readily obtained.
[4] The crucible holding base is preferably composed of a single material. In this case, the gallium arsenide single crystal having the above-described feature can be more readily obtained.
[5] The material is preferably composed of quartz. In this case, the gallium arsenide single crystal having the above-described feature can be more readily obtained.
[6] The material is preferably non-transparent. In this case, the gallium arsenide single crystal having the above-described feature can be more readily obtained.
[7]A method of producing a gallium arsenide single crystal substrate according to one embodiment of the present disclosure is a method of producing a gallium arsenide single crystal substrate having a main surface having a circular shape. The production method includes obtaining the gallium arsenide single crystal substrate by cutting the gallium arsenide single crystal obtained by the method of producing the gallium arsenide single crystal into a disk shape and by processing the gallium arsenide single crystal. According to the method of producing the gallium arsenide single crystal substrate with such a feature, a gallium arsenide single crystal substrate having a large diameter and a very small average value of dislocation density in its main surface having a relatively large off angle is obtained. Thus, even when a semiconductor layer is formed on the main surface, a semiconductor device can be obtained from the gallium arsenide single crystal substrate with an excellent yield.
[8]A gallium arsenide single crystal substrate according to one embodiment of the present disclosure is a gallium arsenide single crystal substrate having a main surface having a circular shape. A diameter of the gallium arsenide single crystal substrate is 200 mm or more and 210 mm or less. The main surface is a plane having an off angle of 4° or more and 20° or less with respect to a (100) plane of the gallium arsenide single crystal. An off direction of the plane having the off angle is any one of a [01-1] direction, a [0-1-1] direction, a [0-11] direction, or a [011] direction. An average value of a dislocation density of the main surface is 0 cm⁻² or more and 3.77 cm⁻² or less. In an imaginary grid formed by laying out squares each having each side of 2 mm on the main surface such that a largest number of the squares are arranged side by side without overlapping with each other, a ratio of the number of squares in each of which no dislocation is present to a total number of the squares constituting the grid is 98.04% or more. The gallium arsenide single crystal substrate includes silicon. A concentration of the silicon is 1.0×10¹⁸ cm⁻³ or more and 5.0×10¹⁹ cm⁻³ or less. A carrier concentration of the gallium arsenide single crystal substrate is 0.8×10¹⁸ cm⁻³ or more and 4.0×10¹⁸ cm⁻³ or less. The gallium arsenide single crystal substrate with such a feature has a large diameter and a very small average value of dislocation density or the like in its main surface having a relatively large off angle. Thus, even when a semiconductor layer is formed on the main surface, a semiconductor device can be obtained from the gallium arsenide single crystal substrate with an excellent yield.
[9] The gallium arsenide single crystal substrate preferably includes boron. A concentration of the boron is preferably 1.0×10¹⁹ cm⁻³ or more and 1.0×10¹⁹ cm⁻³ or less. In this case, the gallium arsenide single crystal substrate has a lower number of dislocations.
[10]A gallium arsenide single crystal according to one embodiment of the present disclosure is a gallium arsenide single crystal having a columnar shape. A diameter of the circular surface that forms a surface of the gallium arsenide single crystal is 200 mm or more and 210 mm or less. The circular surface is a plane having an off angle of 4° or more and 200 or less with respect to a (100) plane of the gallium arsenide single crystal. An off direction of the plane having the off angle is any one of a [01-1] direction, a [0-1-1] direction, a [0-11] direction, or a [011] direction. An average value of a dislocation density in the circular surface is 0 cm⁻² or more and 3.77 cm⁻² or less. In an imaginary grid formed by laying out squares each having each side of 2 mm on the circular surface such that a largest number of the squares are arranged side by side without overlapping with each other, a ratio of the number of squares in each of which no dislocation is present to a total number of the squares constituting the grid is 98.04% or more. The gallium arsenide single crystal includes silicon. A concentration of the silicon is 1.0×10¹⁸ cm⁻³ or more and 5.0×10¹⁹ cm⁻³ or less. A carrier concentration of the gallium arsenide single crystal is 0.8×10¹⁸ cm⁻³ or more and 4.0×10¹⁸ cm⁻³ or less. In the gallium arsenide single crystal with such a feature, thermal strain in the crystal is very small. Thus, the gallium arsenide single crystal is provided as a material for producing a gallium arsenide single crystal substrate having a large diameter and a very small average value of dislocation density or the like in its main surface having a relatively large off angle.
[11]A length of the columnar shape in an axial direction of the columnar shape is preferably 40 mm or more and 110 mm or less. In this case, a large number of gallium arsenide single crystal substrates each having the above-described feature are provided
[12] and [13]A carrier concentration of the gallium arsenide single crystal at one end of the gallium arsenide single crystal is 0.8×10¹⁸ cm⁻³ or more and 1.5×10¹⁸ cm⁻³ or less. A carrier concentration of the gallium arsenide single crystal at the other end of the gallium arsenide single crystal is 1.5×10¹⁸ cm⁻³ or more and 3.5×10¹⁸ cm⁻³ or less. In this case, a large number of gallium arsenide single crystal substrates each having the above-described feature are provided.

### DETAILS OF EMBODIMENTS

Hereinafter, one embodiment (hereinafter, also referred to as “the present embodiment”) according to the present disclosure will be described more in detail, but the present disclosure is not limited thereto. Although explanation may be made in the description below with reference to figures, the same or corresponding elements will be denoted by the same reference characters in the present specification and figures, and the same explanation therefor will not be described repeatedly. Moreover, in each of the figures, the scale of each component is appropriately adjusted in order to facilitate understanding, and the scale of each component shown in each of the figures does not necessarily coincide with the actual scale of the component.

In the present specification, the expression “A to B” represents a range of lower to upper limits (i.e., A or more and B or less), and when no unit is indicated for A and a unit is indicated only for B, the unit of A is the same as the unit of B. Moreover, when a compound or the like is expressed by a chemical formula in the present specification and an atomic ratio is not particularly limited in the chemical formula, it is assumed that all the conventionally known atomic ratios are included, and the atomic ratio should not be necessarily limited only to one in the stoichiometric range.

In the present specification, the term “device yield” means a yield obtained by multiplying a processing yield and a performance yield, the processing yield indicating a ratio at which a wafer (for example, a micro-LED (Light Emitting Diode; micro LED: μLED)-formed wafer) obtained by forming a semiconductor layer on a gallium arsenide single crystal substrate can be obtained from the substrate without occurrence of cracking, chipping, or the like during processing of the substrate, the performance yield indicating a ratio at which the μLED obtained from the wafer can satisfy a required predetermined performance. The “device yield” can be expressed by a percentage. The “processing yield” can be expressed by a ratio at which cracking, chipping, or the like does not occur in the substrate in a series of steps from a step of performing epitaxial growth to form the semiconductor layer or the like on the gallium arsenide single crystal substrate to a step of forming the μLED-formed wafer. The “performance yield” can be expressed by a ratio of non-defective products as obtained by performing an accelerated deterioration test through burn-in onto the μLEDs obtained from the wafer and determining whether each of the μLEDs is non-defective or defective in accordance with a degree of deterioration after the test. Examples of the wafer obtained by forming the semiconductor layer on the substrate also include a vertical-cavity-surface-emitting-laser (Vertical Cavity Surface Emitting Laser: VCSEL)-formed wafer. In this case, the “processing yield” can be expressed by a ratio at which cracking, chipping, or the like does not occur in the substrate in a series of steps from a step of performing epitaxial growth to form the semiconductor layer or the like on the gallium arsenide single crystal substrate to a step of forming the VCSEL-formed wafer. The “performance yield” can be expressed by a ratio of non-defective products as obtained by performing an accelerated deterioration test through burn-in onto the VCSELs obtained from the wafer and determining whether each of the VCSELs is non-defective or defective in accordance with a degree of deterioration after the test.

In the present specification, a “main surface” of the gallium arsenide single crystal substrate means each of two circular surfaces of the substrate. When at least one of the two surfaces of the gallium arsenide single crystal substrate satisfies the scope of claims with regard to the present disclosure, the gallium arsenide single crystal substrate falls within the scope of the present invention. An epitaxial film may be disposed on the “main surface” of the gallium arsenide single crystal substrate. Moreover, in the present specification, the term “plane” used in the expression “in-plane”or “in the plane” means the “main surface” When it is described that the diameter of the gallium arsenide single crystal substrate is “8 inches” in the present specification, it means that the diameter falls within a range of 200 mm or more and 210 mm or less. The diameter is measured by using a known outer diameter measurement device such as a caliper.

In the present specification, a “circular surface that forms a surface” of a gallium arsenide single crystal means each of two circular surfaces included in surfaces of a single crystal having a columnar shape. When at least one of the two circular surfaces of the gallium arsenide single crystal satisfies the scope of claims with regard to the present disclosure, the gallium arsenide single crystal falls within the scope of the present invention. When it is described that the diameter of the “circular surface that forms the surface” of the gallium arsenide single crystal is “8 inches” in the present specification, it means that the diameter falls within a range of 200 mm or more and 210 mm or less. The diameter of the gallium arsenide single crystal is also measured by using a known outer diameter measurement device such as a caliper.

Regarding crystallographic indications in the present specification, an individual orientation is represented by [ ], a group orientation is represented by < >, and an individual plane is represented by ( ), and a group plane is represented by { }. Moreover, a negative crystallographic index is normally expressed by putting “-” (bar) above a numeral, but is expressed by putting the negative sign before the numeral when stated in the present specification.

### [Method of Producing Gallium Arsenide Single Crystal]

A method of producing a gallium arsenide single crystal (GaAs single crystal) according to the present embodiment is a method of producing a gallium arsenide single crystal having a columnar shape. The production method includes a step of growing the GaAs single crystal from a seed crystal using a gallium arsenide single crystal production apparatus (GaAs single crystal production apparatus). A growth side surface of the seed crystal is a plane having an off angle of 4° or more and 20° or less with respect to a (100) plane of the gallium arsenide single crystal. The GaAs single crystal production apparatus includes a crucible having a portion having a cylindrical shape, a crucible holding base that holds the crucible, and a heating element that heats the crucible. The crucible includes a seed crystal accommodation portion, an increased-diameter portion connected to the seed crystal accommodation portion, and a straight barrel portion connected to the increased-diameter portion on a side opposite to the seed crystal accommodation portion side. The seed crystal accommodation portion has a cavity portion having a cylindrical shape, the cavity portion being opened on a side on which the seed crystal accommodation portion is connected to the increased-diameter portion, the cavity portion being provided with a bottom wall formed on a side opposite to the increased-diameter portion. The increased-diameter portion has a truncated conical shape having a diameter that is increased upward in an axial direction of the crucible, and is connected to the seed crystal accommodation portion on a small-diameter side of the increased-diameter portion. The straight barrel portion has a hollow cylindrical shape and is connected to a large-diameter side of the increased-diameter portion. The crucible holding base holds the increased-diameter portion. The increased-diameter portion is constituted of an upper region and a lower region. The upper region is separated from the crucible holding base, and the lower region is in contact with the crucible holding base.

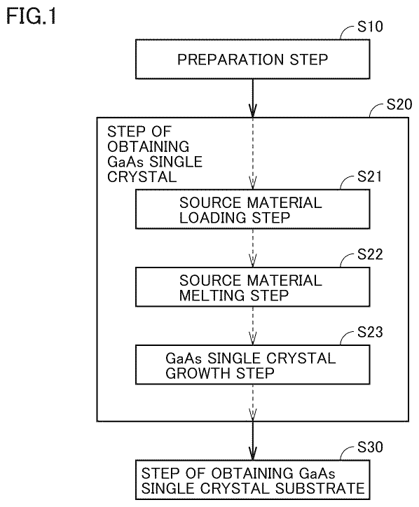

Specifically, the above-described production method preferably has steps as shown in the flowchart of FIG. 1, for example. FIG. 1 is a flowchart showing an example of each of the method of producing the gallium arsenide single crystal and a method of producing the gallium arsenide single crystal substrate according to the present embodiment. According to FIG. 1, the method of producing the GaAs single crystal includes: a step S10 (first step: preparation step) of preparing the GaAs single crystal growth apparatus, the seed crystal, and lump-shaped gallium arsenide (hereinafter, also referred to as “lump-shaped GaAs”); and a step S20 (second step: step of obtaining the GaAs single crystal) of growing the GaAs single crystal from the seed crystal using the GaAs single crystal production apparatus. Further, according to FIG. 1, the method of producing the GaAs single crystal substrate preferably includes a step S30 (third step step of obtaining the GaAs single crystal substrate) of obtaining the GaAs single crystal substrate by cutting the GaAs single crystal obtained by the method of producing the GaAs single crystal into a disk shape and by processing the GaAs single crystal.

Step S20 of obtaining the GaAs single crystal includes: a step (source material loading step S21) of accommodating the seed crystal in a seed crystal accommodation portion and accommodating the lump-shaped GaAs together with silicon in each of the increased-diameter portion and the straight barrel portion; a step (source material melting step S22) of melting a part of the seed crystal and the lump-shaped GaAs into a gallium arsenide melt (hereinafter, also referred to as “GaAs melt”) by heating the crucible using the heating element, and bringing the GaAs melt into contact with a remainder of the seed crystal; and a step (GaAs single crystal growth step S23) of growing the GaAs single crystal from the GaAs melt on the remainder of the seed crystal.

In particular, in GaAs single crystal growth step S23, the thermal environment of the GaAs single crystal growth apparatus is controlled so as to satisfy a relation of q(A1)<q(A2), where q represents a heat flux in a direction from an inner portion of the crucible toward the crucible holding base, A1 represents the upper region, A2 represents the lower region, q(A1) represents an amount of the heat flux passing through the upper region, and q(A2) represents an amount of the heat flux passing through the lower region. That is, in GaAs single crystal growth step S23, the amount (q(A2)) of the heat flux passing through the lower region is always controlled to be larger than the amount (q(A1)) of the heat flux passing through the upper region.

In order to solve the above-described problem, the present inventor has paid attention to performing step S20 of obtaining the GaAs single crystal while satisfying the relation of q(A1)<q(A2) by controlling the thermal environment of the GaAs single crystal growth apparatus that grows the GaAs single crystal serving as a source material of the GaAs single crystal substrate. Specifically, reviews have been made with regard to not only the control of thermal output in the heating element but also the structure of the increased-diameter portion of the crucible included in the apparatus, the structure of the crucible holding base that holds the crucible, and the like. In particular, the present inventor has conceived such a structure that the increased-diameter portion is distinguished into the upper region and the lower region, the upper region is separated from the crucible holding base, and the lower region is in contact with the crucible holding base.

Further, when the surface area of the upper region of the increased-diameter portion is defined as S(A1) and the surface area of the lower region of the increased-diameter portion is defined as S(A2), an attempt is made to attain a structure satisfying the following Formula 1. It should be noted that each of the surface area (S(A1)) of the upper region and the surface area (S(A2)) of the lower region mean the area of a surface of the increased-diameter portion on the crucible holding base side

$$0.2 \leq S ( A 2 ) / ( S ( A 1 ) + S ( A 2 ) ) \leq 0.6 \qquad Formula I$$

Meanwhile, regarding the relation between the increased-diameter portion and the crucible holding base, an attempt is made to arrange the upper region to face the crucible holding base in a direction perpendicular to the growth direction of the GaAs single crystal. Through these trials and errors, it has been found that the thermal distribution in the GaAs single crystal grown in the crucible can be uniform as a result of controlling the heat flux in the direction from the inner portion of the crucible toward the crucible holding base so as to satisfy q(A1)<q(A2). Thus, in the GaAs single crystal substrate obtained from the GaAs single crystal, a very small average value of dislocation density in its main surface having the relatively large off angle can be realized. Moreover, an effect of reducing the dislocation density by doping with the silicon is obtained, thereby achieving a GaAs single crystal substrate having a very small number of dislocations or no dislocations. In view of the above, the present inventor has completed the method of producing the GaAs single crystal so as to obtain a GaAs single crystal substrate having a large diameter and a very small average value of dislocation density or the like in its main surface having a relatively large off angle. In the GaAs single crystal substrate, even when a semiconductor layer is formed on the main surface, a semiconductor device can be obtained with an excellent yield. It should be noted that as the structure of the increased-diameter portion, it is reasonable to employ a structure satisfying a relation of 0.1<S(A2)/(S(A1)+S(A2))<0.8 when the surface area of the upper region is defined as S(A1) and the surface area of the lower region is defined as S(A2).

When the relation between q(A1) and q(A2) does not satisfy the relation of q(A1)<q(A2) and satisfies q(A1)≥q(A2) or the like in step S20 of obtaining the GaAs single crystal, a GaAs single crystal similar to that disclosed in each of the pieces of patent literature described above may be produced. In this case, when an attempt is made to obtain a GaAs single crystal substrate having a large diameter of about 8 inches and a main surface having an off angle of 4° or more with respect to the (100) plane of the GaAs single crystal, the average value of the dislocation density of the main surface becomes deteriorated, with the result that the device yield may be adversely affected. Meanwhile, when the relation between q(A1) and q(A2) does not satisfy the relation of q(A1)<q(A2) and satisfies q(A1)≥q(A2) or the like, there is a possibility that the crystal cannot be grown as a single crystal.

In the course of making reviews to solve the above problem, the present inventor has further found that there is the following concern when a GaAs single crystal is produced by the method disclosed in each of PTL 1 to PTL 5 and NPL 1. That is, it has been found that when a GaAs single crystal substrate having a large diameter of about 200 mm and having a main surface constituted of a plane having an off angle of 4° or more with respect to the (100) plane of the GaAs single crystal is obtained by the method disclosed in each of the above-described prior art documents, an in-plane carrier concentration distribution of the main surface is varied. There is a concern that cracking, chipping, or the like frequently occurs in the GaAs single crystal substrate during processing thereof due to the above variation in the carrier concentration distribution. Based on this finding, the present inventor has performed the above-described step S20 of obtaining the GaAs single crystal using a seed crystal having its surface corresponding to a crystal plane having an off angle of 4° or more and 20° or less with respect to the (100) plane of the GaAs single crystal. As a result, it has been suggested that when a GaAs single crystal substrate is obtained from the GaAs single crystal thus produced, the carrier concentration distribution is very uniform in the main surface of the substrate, and therefore, the device yield is favorably affected. Therefore, the GaAs single crystal obtained by the method of producing the GaAs single crystal according to the present disclosure is provided as a material for obtaining a gallium arsenide single crystal substrate having a large diameter and a very small average value of dislocation density or the like in its main surface having a relatively large off angle.

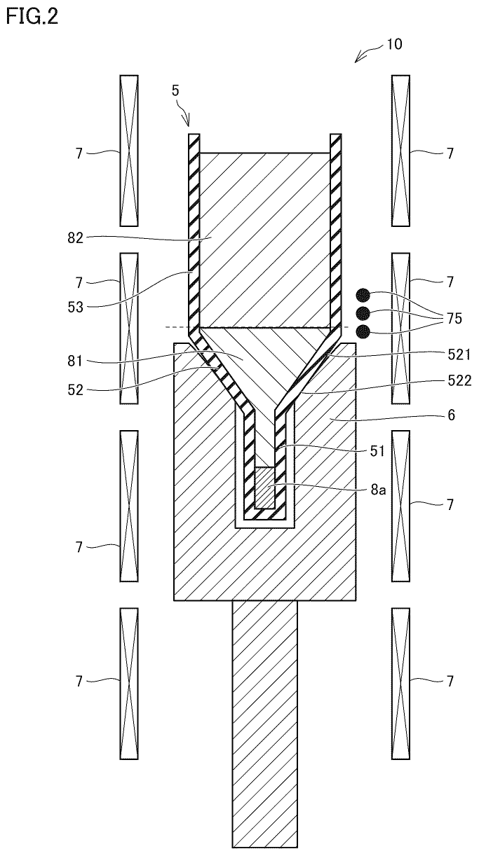

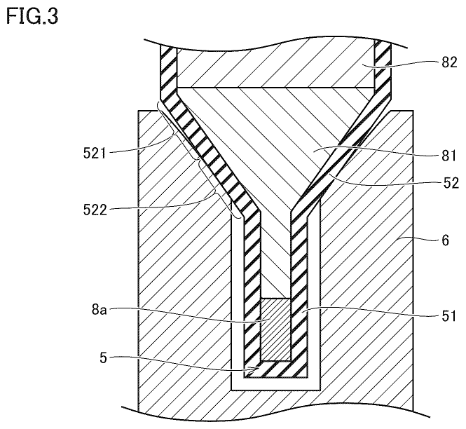

Hereinafter, an overview of the GaAs single crystal growth apparatus and each step included in the method of producing the GaAs single crystal will be described with reference to FIGS. 2 and 3. FIG. 2 is an longitudinal cross sectional view schematically illustrating the gallium arsenide single crystal production apparatus used in the step of growing the gallium arsenide single crystal in the method of producing the gallium arsenide single crystal according to the present embodiment. FIG. 3 is an enlarged view of a main part of FIG. 2. The method of producing the GaAs single crystal according to the present embodiment is a method of producing a GaAs single crystal having a columnar shape. The production method includes a step (step S20 of obtaining the GaAs single crystal) of growing the GaAs single crystal using, for example, a GaAs single crystal growth apparatus 10 shown in FIG. 2. GaAs single crystal growth apparatus 10 includes a crucible 5 having a portion having a cylindrical shape, a crucible holding base 6 that holds crucible 5, and a heating element 7 that heats crucible 5. GaAs single crystal growth apparatus 10 can grow a GaAs single crystal in accordance with a vertical boat method using the crucible. Hereinafter, the vertical boat method will be abbreviated as VB method. The VB method includes a vertical Bridgman method and a vertical temperature gradient solidification method.

### <GaAs Single Crystal Growth Apparatus>

### (Crucible)

As shown in FIG. 2, in GaAs single crystal growth apparatus 10, crucible 5 has a structure having a portion having a cylindrical shape. Specifically, crucible 5 includes a seed crystal accommodation portion 51 having a cylindrical shape, an increased-diameter portion 52 connected to seed crystal accommodation portion 51, and a straight barrel portion 53 connected to increased-diameter portion 52 on a side opposite to the seed crystal accommodation portion 51 side. Seed crystal accommodation portion 51 has a cavity portion, the cavity portion being opened on a side on which seed crystal accommodation portion 51 is connected to increased-diameter portion 52, the cavity portion being provided with a bottom wall formed on a side opposite to the increased-diameter portion 52 side. Seed crystal accommodation portion 51 can accommodate and hold a seed crystal 8a in the cavity portion. Increased-diameter portion 52 has a truncated conical shape having a diameter that is increased upward in an axial direction of crucible 5, and is connected to seed crystal accommodation portion 51 on a small-diameter side of increased-diameter portion 52. Straight barrel portion 53 has a hollow cylindrical shape and is connected to a large-diameter side of increased-diameter portion 52. Each of increased-diameter portion 52 and straight barrel portion 53 has a function of holding lump-shaped GaAs (specifically, polycrystalline gallium arsenide) therein. Further, each of increased-diameter portion 52 and straight barrel portion 53 has a function of growing a GaAs single crystal 81 as a crystalline solid by solidifying a GaAs melt 82 that is a molten state of the lump-shaped GaAs or the like as described later. For crucible 5, various materials, each of which can endure the temperature of GaAs melt 82, are used. For example, pyrolytic boron nitride (pBN) is employed as the material of crucible 5. The inner diameter of straight barrel portion 53 corresponds to the diameter of GaAs single crystal 81 to be grown and is, for example, 200 mm or more and 215 mm or less. Hereinafter, increased-diameter portion 52 will be described more in detail with reference to FIG. 3.

### (Increased-Diameter Portion)

As shown in FIG. 3, increased-diameter portion 52 is constituted of an upper region 521 and a lower region 522. Upper region 521 is separated from crucible holding base 6, and lower region 522 is in contact with crucible holding base 6. Upper region 521 means a region of increased-diameter portion 52 on the upper side in the axial direction. Lower region 522 means a region of increased-diameter portion 52 on the lower side with respect to upper region 521 in the axial direction. A region of increased-diameter portion 52 at which heat flux in the direction from the inner portion of crucible 5 toward crucible holding base 6 is mainly based on radiation is defined as upper region 521. Further, a region of increased-diameter portion 52 at which heat flux in the direction from the inner portion of crucible 5 toward crucible holding base 6 is mainly based on radiation and heat conduction is defined as lower region 522. A boundary between upper region 521 and lower region 522 is determined by a structural difference as to whether upper region 521 and lower region 522 are separated from or in contact with crucible holding base 6. The boundary between upper region 521 and lower region 522 is also determined by a manner of conduction of heat constituting each heat flux in the direction from the inner portion of crucible 5 toward crucible holding base 6.

Since upper region 521 and lower region 522 have the above-described structures in GaAs single crystal growth apparatus 10, the thermal distribution in the GaAs single crystal grown in the crucible can be uniform. Specifically, by the above-described structures of upper region 521 and lower region 522, the heat flux in upper region 521 in the direction from the inner portion of crucible 5 toward crucible holding base 6 can be mainly based on radiation. The heat flux in lower region 522 in the direction from the inner portion of crucible 5 to crucible holding base 6 can be mainly based on radiation and heat conduction. Thus, in GaAs single crystal growth apparatus 10, the heat flux in lower region 522 in the direction from the inner portion of crucible 5 toward crucible holding base 6 can be larger than that in upper region 521 by an amount of heat conduction, with the result that the relation of q(A1)<q(A2) can be readily satisfied.

In particular, according to the structure of upper region 521 separated from crucible holding base 6, the heat flux in upper region 521 in the direction from the inner portion of crucible 5 toward crucible holding base 6 can be mainly based on radiation. Therefore, in GaAs single crystal growth apparatus 10, the thermal distribution in GaAs single crystal 81 that is being grown can be sufficiently uniform by the above structure. Further, according to the structure of lower region 522 in contact with crucible holding base 6, thermal fluctuation occurs in GaAs single crystal 81 that is being grown in GaAs single crystal growth apparatus 10 based on the above-described heat conduction, but the direction of the heat conduction can be a direction toward seed crystal accommodation portion 51 due to the structure of crucible 5. Therefore, GaAs single crystal growth apparatus 10 can significantly suppress the amount of the above-described thermal fluctuation. Therefore, GaAs single crystal growth apparatus 10 can attain very small thermal strain in GaAs single crystal 81 based on the above-described structure.

For example, when the surface area of upper region 521 is defined as S(A1) and the surface area of lower region 522 is defined as S(A2), increased-diameter portion 52 preferably satisfies the following Formula I:

$$0.2 \leq S ( A 2 ) / ( S ( A 1 ) + S ( A 2 ) ) \leq 0.6 . \qquad Formula I$$

With such a structure of increased-diameter portion 52, GaAs single crystal growth apparatus 10 can readily adjust a relation between the amount of the heat flux in upper region 521 in the direction from the inner portion of crucible 5 toward crucible holding base 6 and the amount of the heat flux in lower region 522 in the direction from the inner portion of crucible 5 toward crucible holding base 6 so as to satisfy q(A1)<q(A2). It should be noted that the amount of the heat flux in upper region 521 in the direction from the inner portion of crucible 5 toward crucible holding base 6 means an amount of heat flux passing through upper region 521, and the amount of the heat flux in lower region 522 in the direction from the inner portion of crucible 5 toward crucible holding base 6 means an amount of heat flux passing through lower region 522.

The Formula I is preferably the following Formula I′. Further, S(A2)/(S(A1)+S(A2)) is more preferably 0.5.

$$0.3 \leq S ( A 2 ) / ( S ( A 1 ) + S ( A 2 ) ) \leq 0.5 \qquad Formula {I}^{′}$$

When S(A2)/(S(A1)+S(A2)) is less than 0.2 and when S(A2)/(S(A1)+S(A2)) is more than 0.6, the effect of attaining a very small average value of dislocation density may not become sufficient because the thermal distribution in GaAs single crystal 81 that is being grown may not become sufficiently uniform. In particular, when S(A2)/(S(A1)+S(A2)) is, for example, 0.1 or less, lower region 522 held by crucible holding base 6 is too small, with the result that it becomes difficult to grow GaAs single crystal 81 in a state in which crucible 5 is stabilized, which may adversely affect the growth of GaAs single crystal 81. When (A2)/(S(A1)+S(A2)) is, for example, 0.8 or more, lower region 522 held by crucible holding base 6 is too large, with the result that the relation between q(A1) and q(A2) may become the relation of q(A1)≥q(A2) or the like, which may adversely affect the growth of the GaAs single crystal.

Upper region 521 preferably faces crucible holding base 6 in a direction perpendicular to the growth direction of GaAs single crystal 81. Due to the above-described structure of upper region 521, the heat flux in upper region 521 in the direction from the inner portion of crucible 5 toward crucible holding base 6 is mainly based on radiation. Thus, in step S20 of obtaining the GaAs single crystal, occurrence of the thermal fluctuation in GaAs single crystal 81 that is being grown is suppressed in GaAs single crystal growth apparatus 10 to attain a uniform thermal distribution, with the result that thermal strain in GaAs single crystal 81 can be small.

### (Crucible Holding Base)

GaAs single crystal growth apparatus 10 includes crucible holding base 6 that holds increased-diameter portion 52. Crucible holding base 6 can have, for example, an appearance with a cylindrical shape Crucible holding base 6 is preferably composed of a single material. As the material, for example, quartz, alumina, silicon carbide, or the like can be employed. The material is preferably composed of quartz. In particular, the material is preferably non-transparent. When a material that is non-transparent and that has a poor heat dissipation property is employed for crucible holding base 6, the direction of conduction of the heat constituting the heat flux in lower region 522 can be oriented downward in the axial direction (direction toward seed crystal accommodation portion 51) due to the structure in which lower region 522 is in contact with crucible holding base 6. In this case, crucible holding base 6 can significantly suppress the amount of the above-described thermal fluctuation. The outer diameter of crucible holding base 6 can correspond to or can be the same as the outer diameter of straight barrel portion 53, and is, for example, 215 mm or more and 230 mm or less.

In the present specification, the term “non-transparent” means that transmittance with respect to light having a wavelength of 1600 to 2400 nm is 10% or less. Whether or not the material of crucible holding base 6 is non-transparent is evaluated using, for example, a recording spectrophotometer (product name (item number)): U-4000 provided by Hitachi). Specifically, parallel flat plate samples of a member employed as the material of crucible holding base 6 are prepared to have the same transmittance and the same shape, and each of the samples is measured by the above-described recording spectrophotometer to evaluate whether or not the sample is non-transparent.

### (Heating Element)

GaAs single crystal growth apparatus 10 includes heating element 7 that heats crucible 5. Heating element 7 may consist of two elements. In this case, these two elements are disposed to surround the outer periphery of crucible 5. Each element of heating element 7 is divided into a plurality of portions in a direction perpendicular to the axis of the crucible. Thus, heating element 7 is formed to have multiple stages in each element of heating element 7. Further, an output of heating element 7 can be independently controlled for each element and for each portion. Hence, a temperature at a position of an interface between GaAs single crystal 81 and GaAs melt 82 is strictly controlled. As heating element 7, for example, a known electric heater may be employed.

GaAs single crystal growth apparatus 10 can include thermocouples 75 that each can measure the temperature of crucible 5 heated by heating element 7. The plurality of thermocouples 75 may be disposed outside crucible 5 along the axial direction thereof. In this case, the plurality of thermocouples 75 are preferably disposed outside crucible 5 at least at a height approximately corresponding to the interface between GaAs single crystal 81 and GaAs melt 82 in crucible 5 in the axial direction of crucible 5. Based on the temperatures measured by thermocouples 75, the temperatures of respective portions of GaAs single crystal 81 that is being grown in crucible 5 are estimated. In particular, a temperature distribution in the radial direction at the interface is estimated based on the temperatures measured by thermocouples 75, thereby indirectly evaluating uniformity of the thermal distribution in GaAs single crystal 81 that is being grown. In other words, since the structures of increased-diameter portion 52 and crucible holding base 6 described above are employed and the thermal output of heating element 7 is controlled, the temperatures measured by thermocouples 75 are optimized. Thus, the thermal distribution in GaAs single crystal 81 that is being grown becomes more uniform.

### <Steps Included in Method of Producing GaAs Single Crystal>

### (First Step: Preparation Step S10)

As shown in FIG. 1, in the method of producing the GaAs single crystal substrate according to the present embodiment, first, preparation step S10 is performed as the first step. In preparation step S10, GaAs single crystal growth apparatus 10, seed crystal 8a, and lump-shaped GaAs each for producing the GaAs single crystal are prepared. Seed crystal 8a is composed of a GaAs single crystal. Each of seed crystal 8a and the lump-shaped GaAs may be prepared by a known method, or may be prepared by obtaining a commercially available product.

Seed crystal 8a preferably has a columnar shape such that seed crystal 8a can be accommodated in seed crystal accommodation portion 51. The growth side surface of the seed crystal is a plane having an off angle of 4° or more and 200 or less with respect to the (100) plane of the gallium arsenide single crystal. Specifically, the crystal plane of a circular surface of seed crystal 8a that forms a surface of the columnar shape is a plane inclined with respect to the (100) plane of the GaAs single crystal by one angle selected from an angle range of 4° or more and 20° or less. In this case, the inclined plane is preferably inclined in any one of a [01-1] direction, a [0-1-1] direction, a [0-11] direction, or a [011] direction of the GaAs single crystal. When the method of producing the GaAs single crystal according to the present embodiment is performed using seed crystal 8a having such a feature in terms of the crystal plane, a carrier concentration distribution becomes very uniform in the main surface of the GaAs single crystal substrate obtained from the GaAs single crystal produced by the above-described production method.

### (Second Step: Step S20 of Obtaining GaAs Single Crystal)

Next, in the method of producing the GaAs single crystal substrate according to the present embodiment, step S20 of growing the GaAs single crystal using the GaAs single crystal production apparatus is performed. Step S20 of obtaining the GaAs single crystal includes a source material loading step 521, a source material melting step S22, and a GaAs single crystal growth step S23 as described below. In step S20 of obtaining the GaAs single crystal, these steps are performed in this order.

### 1) Source Material Loading Step S21

Source material loading step S21 is a step of accommodating seed crystal 8a into seed crystal accommodation portion 51 and accommodating the lump-shaped GaAs together with silicon into each of increased-diameter portion 52 and straight barrel portion 53. Source material loading step S21 includes a seed crystal loading step and a gallium arsenide loading step. Source material loading step S21 can further include a sealing material placement step. As shown in FIG. 2, in the seed crystal loading step, seed crystal 8a composed of the GaAs single crystal is loaded into the cavity portion of seed crystal accommodation portion 51 of crucible 5. As a method of loading seed crystal 8a into seed crystal accommodation portion 51, a known method is used, for example. In the gallium arsenide loading step, a plurality of lumps each composed of polycrystalline GaAs are loaded into each of increased-diameter portion 52 and straight barrel portion 53 of crucible 5 as the lump-shaped GaAs, and are stacked on each other. Further, in the gallium arsenide loading step, a predetermined amount of silicon is added to each of increased-diameter portion 52 and straight barrel portion 53 of crucible 5 such that the concentration of the silicon in the GaAs single crystal to be obtained by the present production method becomes 1.0×10¹⁸ cm⁻³ or more and 5.0×10¹⁹ cm⁻³ or less. In the sealing material placement step, a known sealing material (for example, a solid sealing material composed of B₂O₃ (boron oxide)) in the VB method is preferably placed on each of the lumps.

### 2) Source Material Melting Step S22

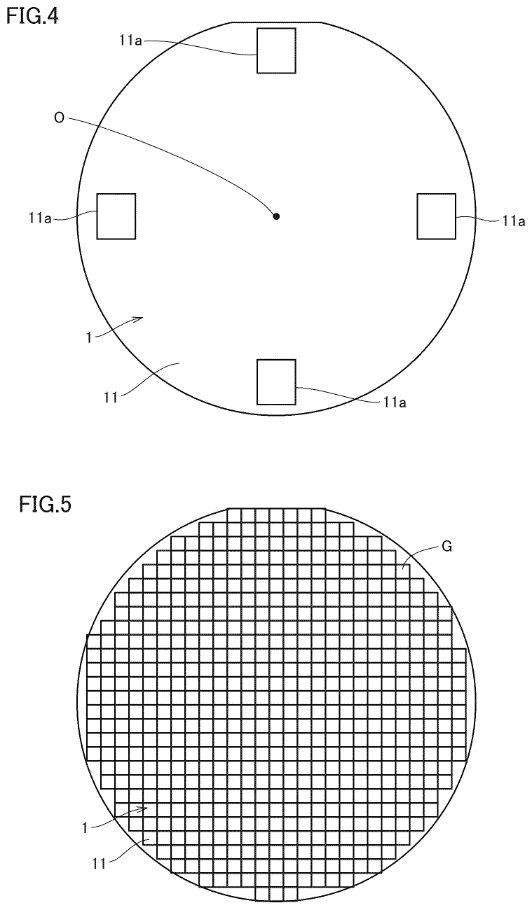

Source material melting step S22 is a step of melting a part of seed crystal 8a and the lump-shaped GaAs into GaAs melt 82 by heating crucible 5 using heating element 7, and bringing GaAs melt 82 into contact with the remainder of seed crystal 8a. In this step, seed crystal 8a and GaAs melt 82 are brought into contact with each other for the purpose of obtaining GaAs single crystal 81. Thus, in the next step of the present production method, crystal growth of GaAs single crystal 81 can be attained on the remainder of seed crystal 8a. Specifically, in source material melting step S22, crucible 5 in which seed crystal 8a, the lump-shaped GaAs, and, preferably, the solid sealing material are placed is supported by crucible holding base 6. On this occasion, as described above, upper region 521 of increased-diameter portion 52 of crucible 5 is separated from crucible holding base 6, and lower region 522 is in contact with crucible holding base 6. Thereafter, a current is supplied to heating element 7 to heat crucible 5. Thus, the lump is melted to become GaAs melt 82. Next, a part of seed crystal 8a is also melted, and the remainder of seed crystal 8a and GaAs melt 82 are brought into contact with each other at an interface therebetween. When the solid sealing material is placed on the lump in source material loading step 521, the lump is preferably melted to become GaAs melt 82 and the sealing material is also preferably melted to become a liquid sealing material (not shown in FIG. 4).

### 3) GaAs Single Crystal Growth Step S23

GaAs single crystal growth step S23 is a step of performing crystal growth of GaAs single crystal 81 from GaAs melt 82 on the remainder of seed crystal 8a. In GaAs single crystal growth step S23, for example, by gradually pulling down crucible 5 (the seed crystal accommodation portion 51 side) along the axis thereof with respect to heating element 7, a temperature gradient is formed in which a temperature on the seed crystal 8a side is low and a temperature on the GaAs melt 82 side is high in crucible 5. Thus, GaAs melt 82 in contact with seed crystal 8a is solidified, with the result that the crystal growth of GaAs single crystal 81 is continuously performed from GaAs melt 82 on the remainder of seed crystal 8a. A speed of pulling down crucible 5 along the axis thereof is not particularly limited, but is, for example, 1 to 5 mm/hour.

GaAs single crystal growth step S23 is performed while controlling the thermal environment in the GaAs single crystal production apparatus based on the above-described structure in which upper region 521 of increased-diameter portion 52 of crucible 5 is separated from crucible holding base 6 and lower region 522 is in contact with crucible holding base 6 and the structure of crucible holding base 6. Specifically, the heat flux in upper region 521 in the direction from the inner portion of crucible 5 toward crucible holding base 6 is mainly based on radiation. Further, the heat flux in lower region 522 in the direction from the inner portion of crucible 5 toward crucible holding base 6 is mainly based on radiation and heat conduction. Thus, GaAs single crystal growth step S23 is performed while satisfying the relation of q(A1)<q(A2), where q represents the heat flux in the direction from the inner portion of crucible 5 toward crucible holding base 6, A1 represents upper region 521, A2 represents lower region 522, q(A1) represents the amount of the heat flux passing through upper region 521, and q(A2) represents the amount of the heat flux passing through lower region 522.

In particular, when the surface area of upper region 521 is defined as S(A1) and the surface area of lower region 522 is defined as S(A2), increased-diameter portion 52 preferably satisfies the following Formula I in order to readily satisfy the relation of q(A1)<q(A2):

$$0.2 \leq S ( A 2 ) / ( S ( A 1 ) + S ( A 2 ) ) \leq 0.6 . \qquad Formula I$$

Further, in order to readily satisfy the relation of q(A1)<q(A2), upper region 521 preferably faces crucible holding base 6 in the direction perpendicular to the growth direction of GaAs single crystal 81.

In GaAs single crystal growth step S23, by continuously pulling down crucible 5 with respect to heating element 7 along the axis thereof, the interface between GaAs single crystal 81 and GaAs melt 82 is raised to the liquid sealing material side and GaAs melt 82 is solidified. Thus, the crystal growth of GaAs single crystal 81 can be attained upward along the axis of crucible 5 in GaAs single crystal growth step S23. The crystal growth of GaAs single crystal 81 is continued until the solidification of GaAs melt 82 remaining in straight barrel portion 53 of crucible 5 is completed. In this way, an ingot of GaAs single crystal 81 is obtained.

Here, the carrier concentration of the ingot of GaAs single crystal 81 is preferably 0.8×10¹⁸ cm⁻³ or more and 1.5×10¹⁸ cm⁻³ or less when the solidification ratio is 0.3. The carrier concentration of the ingot of GaAs single crystal 81 is preferably 2.5×10¹⁸ cm⁻³ or more and 3.5×10¹⁸ cm⁻³ or less when the solidification ratio is 0.85. In the present specification, when the ingot is cut in the direction perpendicular to the growth direction thereof so as to produce a columnar body formed to correspond to a range from the seed crystal side end of the ingot to the cut surface of the ingot, the term “solidification ratio” means a ratio of a mass of the columnar body to the total mass of the ingot. That is, the “solidification ratio” refers to a parameter indicating a degree of proceeding of solidification in response to the growth of the ingot in the process of starting solidification of GaAs melt 82 from the side in contact with seed crystal 8a and growing the ingot of GaAs single crystal 81 in GaAs single crystal growth step S23. Therefore, a state in which the whole of GaAs melt 82 is in a molten state is represented as a solidification ratio of 0, a state in which the whole of GaAs melt 82 is in a solidified state is represented as a solidification ratio of 1, and a state in which solidification proceeding from the seed crystal 8a side has proceeded to 50 mass % of the whole of GaAs melt 82 is represented as a solidification ratio of 0.5. The carrier concentration of the GaAs single crystal and the method of measuring the carrier concentration of the GaAs single crystal substrate will be described later.

### Functions and Effects

According to the method of producing the GaAs single crystal in the present embodiment, in step S20 (particularly, GaAs single crystal growth step S23) of obtaining the GaAs single crystal, GaAs single crystal 81 is grown with the thermal environment of GaAs single crystal growth apparatus 10 being controlled. Thus, occurrence of thermal fluctuation in GaAs single crystal 81 that is being grown is suppressed and thermal distribution becomes uniform, with the result that thermal strain in the crystal becomes as small as possible even in a large single crystal having a diameter of about 8 inches. In this way, a GaAs single crystal for obtaining a GaAs single crystal substrate having a large diameter and a very small average value of dislocation density or the like in its main surface having a relatively large off angle is produced. Thus, even when a semiconductor layer is formed on the main surface, a semiconductor device can be produced from the GaAs single crystal substrate with an excellent yield.

In the above-described production method, the growth direction of GaAs single crystal 81 is preferably a direction normal to the circular surface of seed crystal 8a that forms the surface of the columnar shape. That is, the growth direction of GaAs single crystal 81 is preferably a direction normal to a plane inclined, by one angle selected from an angle range of 4° or more and 20° or less, with respect to the (100) plane of the GaAs single crystal in any one of the [01-1] direction, the [0-1-1] direction, the [0-11] direction, or the [011] direction of the GaAs single crystal. Further, as described later, the GaAs single crystal substrate according to the present embodiment is obtained by cutting the ingot of the GaAs single crystal to have, as its main surface, a plane inclined with respect to the (100) plane of the GaAs single crystal by one angle selected from the above-described angle range of 4° or more and 20° or less. Here, the cutting may be performed in the direction perpendicular to the growth direction of GaAs single crystal 81. Thus, the carrier concentration distribution becomes very uniform in the plane of the main surface of the GaAs single crystal substrate produced by the above production method. It should be noted that when the growth direction of GaAs single crystal 81 is a direction normal to an angle of more than 20° with respect to the (100) plane of the GaAs single crystal, there is a possibility that the above-described desired GaAs single crystal having a small average value of dislocation density cannot be grown.

### [Method of Producing GaAs Single Crystal Substrate]

### <Third Step: Step S30 of Obtaining GaAs Single Crystal Substrate>

The method of producing the gallium arsenide single crystal substrate (GaAs single crystal substrate) according to the present embodiment is a method of producing a GaAs single crystal substrate having a main surface having a circular shape. As shown in FIG. 1, the production method includes: a step (step S30 of obtaining the GaAs single crystal substrate) of obtaining the GaAs single crystal substrate by cutting the GaAs single crystal obtained by the method of producing the GaAs single crystal into a disk shape and by processing the GaAs single crystal. Specifically, step S30 of obtaining the GaAs single crystal substrate includes: a cutting step of obtaining a GaAs single crystal substrate precursor by cutting the GaAs single crystal obtained by the above-described method of producing the GaAs single crystal into the disk shape; and an outer periphery grinding step of obtaining the GaAs single crystal substrate having the main surface having the circular shape by processing the outer periphery of the GaAs single crystal substrate precursor by grinding or the like. Step S30 of obtaining the GaAs single crystal substrate includes the following cutting step, outer peripheral grinding step, and, as necessary, a polishing step described later, and these steps may be performed in this order.

The cutting step is a step of slicing the ingot into a wafer having a predetermined thickness in order to obtain the GaAs single crystal substrate precursor having the disk shape from the ingot composed of GaAs single crystal 81 taken out from crucible 5. Further, the outer periphery grinding step is a step of obtaining the GaAs single crystal substrate having the main surface having the circular shape by grinding the outer periphery of the GaAs single crystal substrate precursor. For the cutting step and the outer periphery grinding step, a known cutting method and a known outer periphery grinding method may be used. Further, the polishing step is a step of forming the main surface into a mirror surface. For the polishing step, a known polishing method may be used.

### Functions and Effects

By performing the above steps, the GaAs single crystal substrate having the main surface having the circular shape is produced. According to the method of producing the GaAs single crystal substrate in the present embodiment, the GaAs single crystal substrate is produced from the GaAs single crystal having a small number of dislocations or no dislocation as produced by the above-described method of producing the GaAs single crystal, thereby providing the GaAs single crystal substrate by which the device yield can be improved.

### [Gallium Arsenide Single Crystal Substrate]

FIG. 4 is an explanatory plan view illustrating the main surface of the gallium arsenide single crystal substrate according to the present embodiment and a measurement target location (measurement target region) for measuring the carrier concentration in the substrate. As shown in FIG. 4, a gallium arsenide single crystal substrate (GaAs single crystal substrate) 1 according to the present embodiment is a GaAs single crystal substrate having a main surface 11 having a circular shape. The diameter of GaAs single crystal substrate 1 is 200 mm or more and 210 mm or less. Main surface 11 is a plane having an off angle of 4° or more and 200 or less with respect to the (100) plane of the GaAs single crystal. The off direction of the plane having the off angle is any one of the [01-1] direction, the [0-1-1] direction, the [0-11] direction, or the [011] direction. The average value of the dislocation density of main surface 11 is 0 cm⁻² or more and 3.77 cm⁻² or less. In an imaginary grid formed by laying out squares each having each side of 2 mm on main surface 11 such that the largest number of the squares are arranged side by side without overlapping with each other, a ratio of the number of squares in each of which no dislocation is present to the total number of the squares constituting the grid is 98.04% or more. GaAs single crystal substrate 1 includes silicon. The concentration of the silicon is 1.0×10¹⁸ cm⁻³ or more and 5.0×10¹⁹ cm⁻³ or less. The carrier concentration of GaAs single crystal substrate 1 is 0.8×10¹⁸ cm⁻³ or more and 4.0×10¹⁸ cm⁻³ or less. In GaAs single crystal substrate 1 having such a feature, the average value of the dislocation density or the like in the main surface having a relatively large off angle is very small. Thus, in GaAs single crystal substrate 1, a semiconductor device can be obtained with an excellent yield even when a semiconductor layer is formed on main surface 11.

GaAs single crystal substrate 1 can improve the device yield due to the following reason. That is, GaAs single crystal substrate 1 is obtained from, for example, the GaAs single crystal produced by the above-described method of producing the GaAs single crystal, or is preferably produced by the above-described method of producing the GaAs single crystal substrate. Therefore, even though GaAs single crystal substrate 1 is a large single crystal having a diameter of about 8 inches as described above, GaAs single crystal substrate 1 can be composed of a GaAs single crystal having a small number of dislocations or no dislocations and produced to attain thermal strain as small as possible in the crystal. Moreover, GaAs single crystal substrate 1 is preferably composed of the GaAs single crystal grown from the seed crystal in which the circular surface that forms the surface of the columnar shape is a plane inclined with respect to the (100) plane of the GaAs single crystal by one angle selected from the angle range of 4° or more and 20° or less. In GaAs single crystal substrate 1 having such a feature, the average value of the in-plane dislocation density of main surface 11 is very small, and the carrier concentration distribution is also very uniform. Thus, cracking, chipping, or the like can be avoided in GaAs single crystal substrate 1 during processing. Further, many of semiconductor devices in each of which a semiconductor layer is formed on GaAs single crystal substrate 1 can satisfy predetermined performance. In view of the above, it is considered that even when the semiconductor layer is formed on the main surface of GaAs single crystal substrate 1 having a large diameter and a relatively large off angle (specifically, 4° or more and 20° or less), the semiconductor device can be produced with an excellent yield.

### <Main Surface>

GaAs single crystal substrate 1 has main surface 11 having the circular shape as described above. In the present specification, the “circular shape” representing the shape of the main surface includes not only a geometric circular shape but also a shape when the main surface does not form the geometric circular shape due to formation of at least one of a notch, an orientation flat (hereinafter, also referred to as “OF”), and an index flat (hereinafter, also referred to as “IF”) in an outer periphery of the main surface. Here, the “shape when the main surface does not form the geometric circular shape” means a shape when the length of a line segment extending from any point on the notch, OF, and IF to the center of the main surface is short among line segments each extending from any point on the outer periphery of the main surface to the center of the main surface. Further, the “shape when the main surface does not form the geometric circular shape” also includes a shape when the lengths of all the line segments each extending from any point on the outer periphery of the main surface to the center of the main surface are not necessarily the same due to the shape of a GaAs single crystal serving as a source material for the GaAs single crystal substrate. In this case, the center of the main surface refers to the position of the center of gravity. The diameter of the GaAs single crystal substrate refers to the length of the longest line segment among the line segments each extending from any point on the outer periphery of the GaAs single crystal substrate to another point on the outer periphery via the center of the main surface.

The surface roughness of main surface 11 is preferably 0.3 nm or less in terms of surface roughness Sa defined in JIS B 0681-2:2018. Thus, main surface 11 of GaAs single crystal substrate 1 becomes a mirror surface, thereby contributing to improved device property. Surface roughness Sa of main surface 11 is more preferably 0.2 nm or less, and is still more preferably 0.1 nm or less. Surface roughness Sa of main surface 11 is measured by using an intermittent contact mode of a known atomic force microscope (for example, product name: “Dimension 3000” provided by Bruker). More specifically, the measurement is performed in such a manner that a size of 512×512 pixels for calculating surface roughness Sa using the atomic force microscope is caused to correspond to any square region having a length of 0.2 μm×a width of 0.2 μm on main surface 11. Thus, surface roughness Sa in the region is determined.

Surface roughness Sa does not need to be 0.3 nm or less in each of all the regions having been subjected to the measurement on main surface 11, and surface roughness Sa measured in at least one region of the plurality of regions set on main surface 11 of GaAs single crystal substrate 1 may be 0.3 nm or less. As the region on main surface 11 for measuring surface roughness Sa, for example, each of the following five regions in total can be selected as the center of a measurement range: center O of GaAs single crystal substrate 1; and any four points (not shown) each located on a circumference located inward by 5 mm from the outer edge of GaAs single crystal substrate 1.

### (Off Angle and Off Direction)

Main surface 11 is a plane having an off angle of 4° or more and 20° or less with respect to the (100) plane of the GaAs single crystal. The off direction of the plane having the off angle is any one of the [01-1] direction, the [0-1-1] direction, the [0-11] direction, or the [011] direction. In other words, the [01-1] direction, the [0-1-1] direction, the [0-11] direction, and the [011] direction of the GaAs single crystal are four directions equivalent to the [01-1] direction of the GaAs single crystal, and are crystallographically represented as a <110> direction.

Main surface 11 is preferably a plane having an off angle of 6° or more and 150 or less with respect to the (100) plane of the GaAs single crystal. In this case, GaAs single crystal substrate 1 can further improve the device yield. In the GaAs single crystal substrate having the main surface having the off angle of less than 4° with respect to the (100) plane of the GaAs single crystal, the above-described effects of the present disclosure can be achieved by using other means. It may be difficult to obtain a GaAs single crystal substrate having a main surface having an off angle of more than 20° with respect to the (100) plane of the GaAs single crystal while achieving the effects of the present disclosure, as long as it is based on the method of producing the GaAs single crystal according to the present embodiment described above.

It should be noted that in the present disclosure, it is assumed that the crystal plane of main surface 11 has a precision error of ±0.5°. For example, when main surface 11 is a “plane having an off angle of 6° with respect to the (100) plane of the GaAs single crystal”, it means that main surface 11 may be a plane having an off angle of 5.5° to 6.5° with respect to the (100) plane. The off angle of main surface 11 of GaAs single crystal substrate 1 with respect to the (100) plane is measured by using a known crystal orientation measurement apparatus (for example, the product name (item number): “2991G2” provided by Rigaku).

### <Diameter>

The diameter of GaAs single crystal substrate 1 is 200 mm or more and 210 mm or less. Thus, the device yield can be improved in GaAs single crystal substrate 1 having the large diameter of 200 mm or more and 210 mm or less. Here, the diameter of GaAs single crystal substrate 1 is determined based on the circular shape before the OF, IF, and the like are formed even in the case where the main surface does not have the geometric circular shape due to the influence of the OF, IF, and the like. As described above, the diameter of GaAs single crystal substrate 1 is measured by using a known outer diameter measurement device such as a caliper.

### (Dislocation Density)

The average value of the dislocation density of main surface 11 is 0 cm⁻² or more and 3.77 cm⁻² or less. Further, in the imaginary grid formed by laying out the squares each having each side of 2 mm on main surface 11 such that the largest number of the squares are arranged side by side without overlapping with each other, the ratio (hereinafter, also referred to as “dislocation-free ratio”) of the number of the squares in which no dislocation is present to the total number of the squares constituting the grid is 98.04% or more. Specifically, each of the average value of the dislocation density and the dislocation-free ratio of main surface 11 is determined by counting the number of corroded pits (hereinafter, also referred to as “etch pits”) exhibited in main surface 11 after etching main surface 11 using molten potassium hydroxide. That is, in GaAs single crystal substrate 1 according to the present embodiment, the average value of the number of etch pits is 0 cm⁻² or more and 3.77 cm⁻² or less, and the dislocation-free ratio is 98.04% or more. It should be noted that the upper limit of the dislocation-free ratio is 100%. The definition of the etch pit is not academically the same as the definition of the dislocation, but the etch pit is regarded as being equivalent to the dislocation in the present technical field

### (Method of Calculating the Number of Etch Pits)

FIG. 5 is an explanatory view illustrating a state in which the imaginary grid in which the squares each having each side of 2 mm are laid out on the main surface of the gallium arsenide single crystal substrate shown in FIG. 4 such that the largest number of the squares are arranged side by side without overlapping with each other is set in order to determine the dislocation density in the main surface. Hereinafter, a specific method of calculating the number of the etch pits will be described with reference to FIG. 5.

First, main surface 11 of GaAs single crystal substrate 1 is immersed in the molten potassium hydroxide at 500° C. for 10 minutes. Then, GaAs single crystal substrate 1 is taken out from the molten potassium hydroxide. As a method of immersing GaAs single crystal substrate 1, a known method is used. Next, as shown in FIG. 5, an imaginary grid G formed by laying out squares each having each side of 2 mm on main surface 11 of GaAs single crystal substrate 1 such that the largest number of the squares are arranged side by side without overlapping with each other is set. Further, the number of etch pits exhibited in one visual field of a known optical microscope (for example, product name: “ECLIPSE (registered trademark) LV150N” provided by Nikon) is counted by observing each of the squares constituting imaginary grid G using the optical microscope. In this case, the observation by the optical microscope is performed at a magnification of 50 times. Thus, the one visual field of the optical microscope has a size of 2 mm×2 mm and corresponds to the size of the square. Therefore, the number of the etch pits in each visual field is determined as the number of dislocations in each of the squares constituting imaginary grid G. It should be noted that only an etch pit confirmed to have an area of 100 μm² or more is counted as the number of the etch pits.

Finally, the number of the etch pits counted in each of the squares constituting imaginary grid G is converted into the number thereof per cm². Thus, respective dislocation densities in the squares are calculated. Then, the sum of the dislocation densities is divided by the number of the squares, thereby determining the average value of the dislocation density of the main surface. Further, the above-described dislocation-free ratio is calculated by determining the ratio of the number of the squares in each of which no dislocation is present to the total number of the squares constituting imaginary grid G. In the present specification, the expression “laying out the squares on main surface 11 such that the largest number of the squares are arranged side by side without overlapping with each other” means that: in the case where the squares are laid out on main surface 11 such that the squares are arranged side by side without overlapping with each other, when a square overlaps with the outer periphery and outer side of main surface 11, the square is excluded from the elements constituting imaginary grid G. This is due to the following reason: a fluctuation in the number of dislocations in a region in the vicinity of the outer periphery, which includes the outer periphery and the like of main surface 11 of GaAs single crystal substrate 1, is large among substrates and such a region is normally not used as a material of a semiconductor device.

The average value of the dislocation density of main surface 11 is preferably 0 cm⁻² or more and 3 cm⁻² or less, and is more preferably 0 cm⁻² or more and 2.88 cm⁻² or less. The dislocation-free ratio is preferably 99.0% or more, and is more preferably 99.45% or more. Thus, it is possible to provide a GaAs single crystal substrate more improved in device yield.

### <Dopant>

GaAs single crystal substrate 1 according to the present embodiment includes silicon (Si). The atomic concentration of the Si is 1.0×10¹⁸ cm⁻³ or more and 5.0×10¹⁹ cm⁻³ or less. The atomic concentration of the Si is preferably 1.4×10¹⁸ cm⁻³ or more and 1.0×10¹⁹ cm⁻³ or less, and is more preferably 1.8×10¹⁸ cm⁻³ or more and 5.0×10¹⁸ cm⁻³ or less. In this case, an n type (electron donating type) property is imparted to GaAs single crystal substrate 1 as the conductivity type, and an effect of reducing the dislocation density is obtained.

GaAs single crystal substrate 1 preferably includes boron (B). In this case, the atomic concentration of the B is preferably 1.0×10¹⁸ cm⁻³ or more and 1.0×10¹⁹ cm⁻³ or less. The atomic concentration of the B is more preferably 1.5×10¹⁸ cm⁻³ or more and 5.0×10¹⁸ cm⁻³ or less. In this case, GaAs single crystal substrate 1 has a lower number of dislocations. Each of the atomic concentrations of the Si and the B in GaAs single crystal substrate 1 is measured by using glow discharge mass spectrometry (GDMS). When GaAs single crystal substrate 1 is obtained in accordance with the above-described method of producing the GaAs single crystal, the B is generated by a reaction between silicon added to gallium arsenide serving as the source material and boron oxide serving as a sealing material. In this way, the B may be included in GaAs single crystal substrate 1.

### <Carrier Concentration>

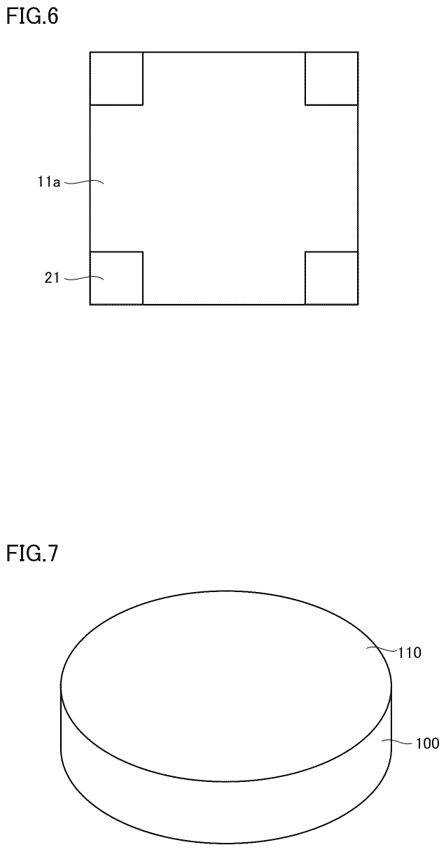

The carrier concentration of GaAs single crystal substrate 1 is 0.8×10¹⁸ cm⁻³ or more and 4.0×10¹⁸ cm⁻³ or less. The carrier concentration is preferably 1.2×10¹⁸ cm⁻³ or more and 3.8×10¹⁸ cm⁻³ or less, and is more preferably 1.4×10¹⁸ cm⁻³ or more and 3.6×10¹⁸ cm⁻³ or less. In this case, the n type (electron donating type) property is imparted to GaAs single crystal substrate 1 as the conductivity type. The carrier concentration of GaAs single crystal substrate 1 is determined through Hall measurement in which the Van der Pauw method is applied, at a room temperature of 25° C., to a rectangular piece obtained by cleaving GaAs single crystal substrate 1. The size of the rectangular piece is, for example, a length of 4 mm×a width of 4 mm×a thickness of 600 nm. Hereinafter, the method of measuring the carrier concentration of GaAs single crystal substrate 1 will be described with reference to FIGS. 4 and 6. FIG. 6 is an explanatory view illustrating a Hall measurement sample produced using the gallium arsenide single crystal substrate shown in FIG. 4.

First, one GaAs single crystal substrate 1 to be measured is produced from the GaAs single crystal obtained based on the above-described method of producing the GaAs single crystal. Next, as shown in FIG. 4, in this one GaAs single crystal substrate 1, four intersection points are defined which are points at which a circumference located inward by 5 mm from the outer edge thereof intersects with half lines extending from center O of main surface 11 of GaAs single crystal substrate 1 in the [01-1] direction, the [0-1-1] direction, the [0-11] direction, and the [011] direction of the GaAs single crystal. Further, rectangular pieces 11a each having a size of 4 mm in length×4 mm in width×600 μm in thickness and respectively centered at the above four intersections are produced. Then, as shown in FIG. 6, electrodes 21 each composed of an alloy including gold, nickel, and germanium are formed at four corners of each rectangular piece 11a, thereby obtaining four Hall measurement samples. Here, the shape of each of electrodes 21 is not limited to the rectangular shape shown in the figure, and may be a fan shape or a circular shape. The carrier concentration is determined by applying, under an atmosphere at 25° C., the Hall measurement according to the Van der Pauw method to the four Hall measurement samples including such electrodes 21. It should be noted that in the present specification, the “carrier concentration of the GaAs single crystal substrate” means the average value of the carrier concentrations obtained from the above-described four Hall measurement samples. Further, a value obtained by dividing, by the average value, a value obtained by subtracting the minimum value from the maximum value of the carrier concentrations obtained from the four Hall measurement samples is defined as a second carrier concentration ([max−min]/average) of the GaAs single crystal substrate. The second carrier concentration represents a variation of the carrier concentration in main surface 11 of GaAs single crystal substrate 1, and it is evaluated that as the value thereof is smaller, the carrier concentration distribution in main surface 11 is more uniform.

### [Gallium Arsenide Single Crystal]

FIG. 7 is a perspective view schematically illustrating the gallium arsenide single crystal according to the present embodiment. As shown in FIG. 7, a gallium arsenide single crystal (GaAs single crystal) 100 according to the present embodiment is a GaAs single crystal having a columnar shape. The diameter of a circular surface 110 that forms the surface of GaAs single crystal 100 is 200 mm or more and 210 mm or less. Circular surface 110 is a plane having an off angle of 4° or more and 20° or less with respect to the (100) plane of the GaAs single crystal. The off direction of the plane having the off angle is any one of the [01-1] direction, the [0-1-1] direction, the [0-11] direction, or the [011] direction. The average value of the dislocation density in circular surface 110 is 0 cm⁻² or more and 3.77 cm⁻² or less. In an imaginary grid formed by laying out squares each having each side of 2 mm on circular surface 110 such that a largest number of the squares are arranged side by side without overlapping with each other, a ratio of the number of squares in each of which no dislocation is present to a total number of the squares constituting the grid is 98.04% or more. GaAs single crystal 100 includes silicon. The concentration of the silicon is 1.0×10¹⁸ cm⁻³ or more and 5.0×10¹⁹ cm⁻³ or less. The carrier concentration of GaAs single crystal 100 is 0.8×10¹⁸ cm⁻³ or more and 4.0×10¹⁸ cm⁻³ or less. In GaAs single crystal 100 having such a feature, thermal strain in the crystal is very small. Therefore, GaAs single crystal 100 is provided as a material for producing a GaAs single crystal substrate having a large diameter and a very small average value of dislocation density or the like in its main surface having a relatively large off angle.

In particular, in GaAs single crystal 100, the length of the columnar shape in the axial direction of the columnar shape is preferably 40 mm or more and 110 mm or less. When the length of the columnar shape in the axial direction of the columnar shape is 40 mm or more, a large number of GaAs single crystal substrates with excellent device yields can be provided. When the length of the columnar shape in the axial direction of the columnar shape is 110 mm or less, GaAs single crystal substrates with less variation in carrier concentration per product lot are provided.

The reason why the GaAs single crystal substrate having the improved device yield can be provided by GaAs single crystal 100 is the same as the reason why the device yield can be improved by GaAs single crystal substrate 1 described above, and therefore the same explanation will not be described repeatedly.

### <Circular Surface That Forms Surface of GaAs Single Crystal>

GaAs single crystal 100 has the columnar shape. Thus, GaAs single crystal 100 has circular surface 110 that forms the surface thereof. In the present specification, the shape of circular surface 110 includes a geometric circular shape and a shape when it does not form the geometric circular shape. Here, the “shape of circular surface 110 when it does not form the geometric circular shape” refers to a shape when the lengths of all the line segments each extending from any point on the outer periphery of circular surface 110 to the center of circular surface 110 are not necessarily the same. In this case, the center of circular surface 110 is the position of the center of gravity. The diameter of circular surface 110 is the length of the longest line segment among the line segments each extending from any point on the outer periphery of circular surface 110 to another point on the outer periphery via the center of circular surface 110.

### (Off Angle and Off Direction)

Circular surface 110 is a plane having an off angle of 4° or more and 200 or less with respect to the (100) plane of the GaAs single crystal. The off direction of the plane having the off angle is any one of the [01-1] direction, the [0-1-1] direction, the [0-11] direction, or the [011] direction. The features of the off angle and the off direction of circular surface 110 in GaAs single crystal 100 are the same as the features of the off angle and the off direction of the “main surface 11” of GaAs single crystal substrate 1 described above, and therefore the same explanation will not be described repeatedly. It should be noted that a preferable range of the off angle in circular surface 110 is also the same as the preferable range of the off angle in main surface 11. In the present disclosure, the crystal plane of circular surface 110 has a precision error of 0.5° as with main surface 11 of GaAs single crystal substrate 1.

### <Diameter>

The diameter of circular surface 110 that forms the surface of GaAs single crystal 100 is 200 mm or more and 210 mm or less. As described above, the diameter of circular surface 110 that forms the surface of GaAs single crystal 100 is measured by using a known outer diameter measurement device such as a caliper.

### <Dislocation Density>

The average value of the dislocation density of circular surface 110 is 0 cm⁻² or more and 3.77 cm⁻² or less. Further, in the imaginary grid formed by laying out the squares each having each side of 2 mm on circular surface 110 such that the largest number of the squares are arranged side by side without overlapping with each other, the ratio (dislocation-free ratio) of the number of the squares in which no dislocation is present to the total number of the squares constituting the grid is 98.04% or more. Since the average value of the dislocation density of circular surface 110 and the features and effects regarding the dislocation-free ratio are the same as the average value of the dislocation density of main surface 11 of GaAs single crystal substrate 1 and the features and effects regarding the dislocation-free ratio described above, the same explanation will not be described repeatedly. It should be noted that a preferable average value of the dislocation density and a preferable range of the dislocation-free ratio in circular surface 110 are also the same as the preferable average value of the dislocation density and the preferable range of the dislocation-free ratio in main surface 11. Further, a method of calculating the number of etch pits in circular surface 110 is the same as the method of calculating the number of etch pits in main surface 11. Therefore, the number of etch pits in circular surface 110 is determined by applying the calculation method described above while replacing the term “main surface 11” used in the description of the method of calculating the number of etch pits in main surface 11 with the term “circular surface 110”.

### <Dopant>

GaAs single crystal 100 includes silicon (Si). The atomic concentration of the Si is 1.0×10¹⁸ cm⁻³ or more and 5.0×10¹⁹ cm⁻³ or less. The features and effects regarding the dopant of GaAs single crystal 100 are the same as the features and effects regarding the dopant of GaAs single crystal substrate 1 described above, and therefore the same explanation will not be described repeatedly. It should be noted that GaAs single crystal 100 preferably includes boron (B) as the dopant, and the range of the content (atomic concentration) of the B in this case is also the same as that of GaAs single crystal substrate 1. Further, the concentration of the dopant of GaAs single crystal 100 is also determined by the same measurement method as that for GaAs single crystal substrate 1.

### <Carrier Concentration>

The carrier concentration of GaAs single crystal 100 is 0.8×10¹⁸ cm⁻³ or more and 4.0×10¹⁸ cm⁻³ or less. The features and effects regarding the carrier concentration of GaAs single crystal 100 are the same as the above features and effects regarding the carrier concentration of GaAs single crystal substrate 1, and therefore the same explanation will not be described repeatedly. Further, each of the carrier concentration and the second carrier concentration of GaAs single crystal 100 can also be determined by the same measurement method as that for GaAs single crystal substrate 1. Therefore, each of the carrier concentration and the second carrier concentration in GaAs single crystal 100 is determined by applying the above-described measurement method while replacing the term “main surface 11” used in the description of the method of measuring each of the carrier concentration and the second carrier concentration in GaAs single crystal substrate 1 with the term “circular surface 110”.

In particular, the carrier concentration of GaAs single crystal 100 at one end of GaAs single crystal 100 is preferably 0.8×10¹⁸ cm⁻³ or more and 1.5×10¹⁸ cm⁻³ or less. The carrier concentration of GaAs single crystal 100 at the other end of GaAs single crystal 100 is preferably 1.5×10¹⁸ cm⁻³ or more and 3.5-10¹⁸ cm⁻³ or less. In this case, the n type (electron donating type) property is appropriately imparted to GaAs single crystal 100 as the conductivity type.

When the solidification ratio is 0.3, the carrier concentration of GaAs single crystal 100 is preferably 0.8×10¹⁸ cm⁻³ or more and 1.5×10¹⁸ cm⁻³ or less. When the solidification ratio is 0.85, the carrier concentration of GaAs single crystal 100 is preferably 2.5×10¹⁸ cm⁻³ or more and 3.5×10¹⁸ cm⁻³ or less. In this case, excellent epitaxial growth is performed on the GaAs single crystal substrate obtained from GaAs single crystal 100. In the present specification, as described above, when GaAs single crystal 100 is cut in the direction perpendicular to the growth direction so as to produce the columnar body formed to correspond to the range from the seed crystal side end of GaAs single crystal 100 to the cut surface of GaAs single crystal 100, the “solidification ratio” means the ratio of the mass of the columnar body to the total mass of GaAs single crystal 100.

### EXAMPLES

Hereinafter, the present disclosure will be described more in detail with reference to examples, but the present disclosure is not limited thereto. In the present example, the present inventor produced a GaAs single crystal of each sample in accordance with the vertical Bridgman method using a GaAs single crystal growth apparatus or the like as shown in FIG. 2, and obtained a GaAs single crystal substrate from the GaAs single crystal of each sample. In the following description, samples 11 to 18 and samples 21 to 25 correspond to examples of the present disclosure, and samples 101 to 103 and samples 201 to 203 correspond to comparative examples.

### First Example

### [Production of GaAs Single Crystal Substrate]

The GaAs single crystal substrates of samples 11 to 18 and samples 101 to 103 each having a diameter of 205 mm were produced in the following manner.

### <Sample 101>

### (First Step: Preparation Step S10)

A known GaAs single crystal growth apparatus to which the vertical Bridgman method was applied was prepared, and a seed crystal and lump-shaped GaAs composed of a GaAs polycrystal were prepared through production by known methods. Here, the GaAs single crystal growth apparatus is configured such that the entire surface of the increased-diameter portion on the crucible holding base side is in contact with the crucible holding base. Therefore, the whole of the heat flux in the increased-diameter portion of the crucible of the GaAs single crystal growth apparatus in the direction from the inner portion of the crucible toward the crucible holding base is mainly constituted of radiation and heat conduction, and the whole of the increased-diameter portion is therefore regarded as the lower region. In this case, the value of S(A2)/(S(A1)+S(A2)) represented by the Formula I in the increased-diameter portion is 1 In the GaAs single crystal growth apparatus, the inner diameter of the straight barrel portion of the crucible was 210 mm. The seed crystal had a columnar shape, and the crystal plane of a circular surface that forms the surface of the columnar shape was a plane having an off angle of 4° with respect to the (100) plane in the [011] direction.

### (Second Step: Step S20 of Obtaining GaAs Single Crystal)

### 1) Source Material Loading Step S21

A known method was used to load the seed crystal into the cavity portion in the seed crystal accommodation portion of the crucible provided in the GaAs single crystal growth apparatus. Further, a plurality of pieces of lump-shaped GaAs composed of polycrystalline GaAs were loaded into the increased-diameter portion and the straight barrel portion of the crucible and were stacked on each other. A slight amount of silicon (Si) was also added. Further, a sealing material composed of B₂O₃ was disposed on the lump-shaped GaAs.

### 2) Source Material Melting Step S22

A current was supplied to the heating element to heat the crucible, with the result that the sealing material became a liquid sealing material and the lump-shaped GaAs loaded in each of the increased-diameter portion and the straight barrel portion became a GaAs melt. Further, by controlling the heating element that heats the seed crystal accommodation portion, a part of the seed crystal accommodated in the cavity portion was also melted. Thus, the remainder of the seed crystal and the GaAs melt were brought into contact with each other.

### 3) GaAs Single Crystal Growth Step S23

The output of the heating element that heats the crucible was controlled, and the crucible was gradually pulled downward (the seed crystal accommodation portion side) along its axis with respect to the heating element, thereby forming a temperature gradient in which a temperature on the seed crystal side was low and a temperature on the GaAs melt side was high in the crucible. Thus, a GaAs single crystal was continuously grown from the GaAs melt on the remainder of the seed crystal. It should be noted that a speed of pulling the crucible downward along its axis was 2 mm/hour.

By controlling the output of the heating element that heats the crucible and pulling the crucible downward with respect to the heating element along its axis in GaAs single crystal growth step S23, the GaAs melt was solidified, thereby attaining crystal growth of the GaAs single crystal upward along the axis of the crucible. Thereafter, the crystal growth of the GaAs single crystal was continued until the solidification of the GaAs melt remaining in the straight barrel portion of the crucible was completed, thereby obtaining an ingot of the GaAs single crystal.

Here, when producing the GaAs single crystal substrate of sample 101, the entire surface of the increased-diameter portion on the crucible holding base side is in contact with the crucible holding base, and therefore the whole of the increased-diameter portion is regarded as the lower region. In this case, the whole of the heat flux in the increased-diameter portion in the direction from the inner portion of the crucible toward the crucible holding base is mainly constituted of radiation and heat conduction. Therefore, in GaAs single crystal growth step S23, it was difficult to sufficiently suppress occurrence of thermal fluctuation in GaAs single crystal 81 that is being grown.

### (Third Step: Step S30 of Obtaining GaAs Single Crystal Substrate)

A known cutting method and a known peripheral grinding method were used to obtain, from the ingot of the GaAs single crystal taken out from the crucible, a GaAs single crystal substrate that has a predetermined thickness and that has a main surface having a circular shape. Further, the main surface of the GaAs single crystal substrate was polished by a known method, thereby forming the main surface into a mirror surface. In this way, the GaAs single crystal substrate of sample 101 was obtained. The crystal plane of the main surface of the GaAs single crystal substrate was a plane having an off angle of 4° with respect to the (100) plane in the [011] direction. Further, surface roughness Sa of the main surface of the GaAs single crystal substrate as measured by the above-described measurement method was 0.15 nm.

### <Sample 102>

In preparation step S10, the GaAs single crystal substrate of sample 102 was obtained in the same manner as in sample 101 except that there was prepared a seed crystal which has a columnar shape and in which the crystal plane of a circle that forms the surface of the columnar shape is a plane having an off angle of 6° with respect to the (100) plane in the [011] direction. Therefore, the value of S(A2)/(S(A1)+S(A2)) represented by the above Formula I was 1 in the GaAs single crystal growth apparatus used when producing the GaAs single crystal substrate of sample 102. Further, since the whole of the increased-diameter portion is the lower region and the heat flux in the increased-diameter portion in the direction from the inner portion of the crucible toward the crucible holding base is mainly constituted of radiation and heat conduction in GaAs single crystal growth step S23, it was difficult to sufficiently suppress occurrence of thermal fluctuation in GaAs single crystal 81 that is being grown. The crystal plane of the main surface of the GaAs single crystal substrate of sample 102 was a plane having an off angle of 6° with respect to the (100) plane in the [011] direction. Further, surface roughness Sa of the main surface of the GaAs single crystal substrate as measured by the above-described measurement method was 0.15 nm.

### <Sample 11>

In preparation step S11, the GaAs single crystal substrate of sample 11 was obtained in the same manner as in sample 101 except that there was prepared a GaAs single crystal growth apparatus to which the vertical Bridgman method as shown in FIG. 2 was applied and there was prepared a seed crystal having a columnar shape and having, as a growth surface, a plane having an off angle of 4° with respect to the (100) plane of the GaAs single crystal in the [011] direction. However, the increased-diameter portion of the crucible provided in the GaAs single crystal growth apparatus used when producing the GaAs single crystal substrate of sample 11 had such a structure that the increased-diameter portion was constituted of an upper region and a lower region, the upper region was separated from the crucible holding base, and the lower region was in contact with the crucible holding base. Further, the value of S(A2)/(S(A1)+S(A2)) represented by the above Formula I was 0.5. The crystal plane of the main surface of the GaAs single crystal substrate of sample 11 was a plane having an off angle of 4° with respect to the (100) plane in the [011] direction. Surface roughness Sa of the main surface of the GaAs single crystal substrate as measured by the above-described measurement method was 0.15 nm.

### <Samples 12 to 18 and Sample 103>

In preparation step S10, each of the GaAs single crystal substrates of samples 12 to 18 and sample 103 was obtained in the same manner as in sample 11 except that there was prepared a seed crystal which has a columnar shape and in which the crystal plane of a circle that forms the surface of the columnar shape is a plane inclined by 6 to 22° with respect to the (100) plane in the [011] direction as shown in Table 1 below. Each of the crystal planes of the main surfaces of the GaAs single crystal substrates of samples 12 to 18 and sample 103 was a plane having an off angle of 6 to 22° with respect to the (100) plane in the [011] direction as shown in Table 1 below. Further, surface roughness Sa of the main surface of the GaAs single crystal substrate as measured by the above-described measurement method was 0.15 nm.

Here, samples 12 and 13 are GaAs single crystal substrates obtained from the same ingot of the GaAs single crystal having the off angle of 6°. However, they are different in that sample 12 is a GaAs single crystal substrate obtained from a portion of the ingot at which the solidification ratio was 0.27, and sample 13 is a GaAs single crystal substrate obtained from a portion of the ingot at which the solidification ratio was 0.89 Further, samples 16 and 17 are GaAs single crystal substrates obtained from the same ingot of the GaAs single crystal having the off angle of 15°. However, they are different in that sample 16 is a GaAs single crystal substrate obtained from a portion of the ingot at which the solidification ratio was 0.27 and sample 17 is a GaAs single crystal substrate obtained from a portion of the ingot at which the solidification ratio was 0.89.

### <Evaluation on Properties>

The above-described measurement method or calculation method was performed onto each of the GaAs single crystal substrates of samples 11 to 18 and samples 101 to 103 so as to determine the atomic concentration of the silicon, the carrier concentration, the second carrier concentration, the atomic concentration of the boron, the average value of the dislocation density, and the dislocation-free ratio in each sample. The results are shown in Table 1. It should be noted that Table 1 also shows the off angle of the main surface of the GaAs single crystal substrate of each sample, the structure of the increased-diameter portion (presence or absence of the upper region and the lower region), the value of S(A2)/(S(A1)+S(A2)) represented by the above Formula 1, and the like.

### <Device Yield>

VCSELs were produced using the GaAs single crystal substrates of samples 11 to 18 and samples 101 to 103 in accordance with a method disclosed in Japanese Patent Laying-Open No. 2008-283137. In this case, the device yield (%) was determined by multiplying the processing yield by the performance yield, the processing yield indicating a ratio at which a VCSEL-formed wafer including a plurality of VCSEL portions could be obtained from the GaAs single crystal substrate without occurrence of cracking, chipping, or the like during processing, the performance yield indicating a ratio at which VCSELs obtained from the wafer could each satisfy a required predetermined performance. Here, the “performance yield” was evaluated by the following accelerated deterioration test. It should be noted that the “VCSEL portion” refers to a device-like region that is located on the wafer and that can function as a VCSEL as a result of dividing the VCSEL-formed wafer and performing mounting. The VCSEL portion was divided to provide VCSELs each having a size of 500 μm in length×500 μm in width.

First, before performing the accelerated deterioration test, each VCSEL portion in the VCSEL-formed wafer produced in each sample was subjected to an initial property evaluation in an on-wafer state. In the initial property evaluation, a VCSEL portion having an optical output of 4 mW or more at an operating current of 9 mA was regarded as a non-defective product. Further, a VCSEL portion having an optical output of less than 4 mW at an operating current of 9 mA was marked as a defective portion in the wafer. Next, the wafer was divided into pieces, all of which served as chips. Then, 40 non-defective chips (i.e., unmarked chips) were freely extracted from the chips and mounting was performed, thereby obtaining VCSELs. Further, an applied current of 18 mA was applied to each of the VCSELs for 100 hours at an atmosphere temperature of 80° C., thereby performing the accelerated deterioration test. Thereafter, each VCSEL was returned to the room temperature, and the optical output thereof at an operating current of 9 mA was evaluated. In the above evaluation, a VCSEL in which the optical output was decreased by 10% or less from the optical output before the accelerated deterioration test (i.e., the optical output was 3.6 mW or more) was regarded as a non-defective product, and a ratio of the number of non-defective products to the above 40 products was regarded as the performance yield. The results are shown in Table 1. It should be noted that in Table 1, a sample having a device yield of 90% or more was determined to be A, a sample having a device yield of 80% or more and less than 90% was determined to be B, and a sample having a device yield of less than 80% was determined to be C.

TABLE 1

| | | | | Second | | |
|---|---|---|---|---|---|---|
| | Off | Si | Concentration | Carrier | B | Dislocation |
| | Angle | Concentration | Carrier | Concentration | Concentration | Density |
| | (°) | (cm⁻³) | (cm⁻³) | (*) | (cm⁻³) | (cm⁻²) |
| Sample 101 | 4 | 2.10 × 10¹⁸ | 1.62 × 10¹⁸ | 1.86 × 10⁻² | 2.75 × 10¹⁸ | 130 |
| Sample 102 | 6 | 2.10 × 10¹⁸ | 1.59 × 10¹⁸ | 1.23 × 10⁻² | 2.70 × 10¹⁸ | 164 |
| Sample 11 | 4 | 2.10 × 10¹⁸ | 1.61 × 10¹⁸ | 2.45 × 10⁻² | 2.80 × 10¹⁸ | 2.820 |
| Sample 12 | 6 | 2.10 × 10¹⁸ | 1.60 × 10¹⁸ | 1.22 × 10⁻² | 2.75 × 10¹⁸ | 0.286 |
| Sample 13 | 6 | 2.10 × 10¹⁸ | 3.20 × 10¹⁸ | 3.05 × 10⁻² | 2.70 × 10¹⁸ | 0.048 |
| Sample 14 | 8 | 2.10 × 10¹⁸ | 1.60 × 10¹⁸ | 3.05 × 10⁻² | 2.70 × 10¹⁸ | 0.900 |
| Sample 15 | 10 | 2.00 × 10¹⁸ | 1.59 × 10¹⁸ | 1.23 × 10⁻² | 2.90 × 10¹⁸ | 0.190 |
| Sample 16 | 15 | 2.10 × 10¹⁸ | 1.60 × 10¹⁸ | 2.44 × 10⁻² | 2.75 × 10¹⁸ | 0.529 |
| Sample 17 | 15 | 2.10 × 10¹⁸ | 3.31 × 10¹⁸ | 1.23 × 10⁻² | 2.70 × 10¹⁸ | 0 |
| Sample 18 | 20 | 2.10 × 10¹⁸ | 1.61 × 10¹⁸ | 6.15 × 10⁻² | 2.70 × 10¹⁸ | 3.770 |
| Sample 103 | 22 | 2.10 × 10¹⁸ | 1.59 × 10¹⁸ | 1.23 × 10⁻² | 2.70 × 10¹⁸ | 150 |

| | | | | Structure of | | |
|---|---|---|---|---|---|---|
| | Dislocation- | Device | | Increased- | S(A2)/ | |
| | Free Ratio | Yield | Solidification | Diameter | (S(A1) + | |
| | (%) | (%) | Ratio | Portion | S(A2)) | Determination |
| Sample 101 | 85.70 | 40.5 | 0.27 | Only Lower | 1 * | C |
| | | | | Region | | |
| Sample 102 | 70.68 | 20.5 | 0.27 | Only Lower | 1 * | C |
| | | | | Region | | |
| Sample 11 | 98.04 | 89.9 | 0.27 | Upper Region/ | 0.5 | B |
| | | | | Lower Region | | |
| Sample 12 | 99.84 | 92.1 | 0.27 | Upper Region/ | 0.5 | A |
| | | | | Lower Region | | |
| Sample 13 | 99.97 | 93.5 | 0.89 | Upper Region/ | 0.5 | A |
| | | | | Lower Region | | |
| Sample 14 | 99.45 | 91.3 | 0.27 | Upper Region/ | 0.5 | A |
| | | | | Lower Region | | |
| Sample 15 | 99.53 | 91.5 | 0.27 | Upper Region/ | 0.5 | A |
| | | | | Lower Region | | |
| Sample 16 | 99.51 | 92.0 | 0.27 | Upper Region/ | 0.5 | A |
| | | | | Lower Region | | |
| Sample 17 | 100.0 | 93.5 | 0.89 | Upper Region/ | 0.5 | A |
| | | | | Lower Region | | |
| Sample 18 | 98.04 | 89.8 | 0.27 | Upper Region/ | 0.5 | B |
| | | | | Lower Region | | |
| Sample 103 | 0 | 0 | 0.27 | Upper Region/ | 0.5 | C |
| | | | | Lower Region | | |

* S(A2)/(S(A1) + S(A2)) of 1 means that the entire surface of the increased-diameter portion on the crucible holding base side is in contact with the crucible holding base.
(*) The second carrier concentration is calculated by “[max − min]/average” of the carrier concentrations measured in the Hall measurement samples obtained from four positions on the main surface.

### <Review>

In each of the GaAs single crystal substrates of samples 11 to 18, the off angle of the main surface was 4 to 20°, the average value of the dislocation density of the main surface was 0 cm⁻² or more and 3.77 cm⁻² or less, and the dislocation-free ratio was 98.04% or more. Further, the atomic concentration of the silicon was 1.0×10¹⁸ cm⁻³ or more and 5.0×10¹⁹ cm⁻³ or less, and the carrier concentration was 0.8-10¹⁸ cm⁻³ or more and 4.0×10¹⁸ cm⁻³ or less. Further, the device yield of each of these GaAs single crystal substrates was 89.8% or more, which was determined to be A or B. On the other hand, in each of the GaAs single crystal substrates of samples 101 to 102, the off angle of the main surface was 4 to 6°, but the average value of the dislocation density of the surface was more than 3.77 cm⁻², and the dislocation-free ratio was less than 98.04%. Further, each of the GaAs single crystal substrates of samples 101 to 102 was produced by the GaAs single crystal production apparatus having such a structure that the entire surface of the increased-diameter portion is in contact with the crucible holding base. In this case, the device yield in each of these GaAs single crystal substrates was less than 80%, which was determined to be C. In the GaAs single crystal substrate of sample 103, the off angle of the main surface was 22°, the average value of the dislocation density of the main surface was more than 3.77 cm⁻², and the dislocation-free ratio was less than 98.04%. In this case, the device yield of the GaAs single crystal substrate of sample 103 was less than 80%, which was determined to be C.

### Second Example

### [Production of GaAs Single Crystal Substrate]

GaAs single crystal substrates of samples 21 to 25 and samples 201 to 203 each having a diameter of 205 mm were produced in the following manner.

### <Sample 201>

The GaAs single crystal substrate of sample 102 described above was obtained as the GaAs single crystal substrate of sample 201.

### <Sample 202>

In preparation step S10, a GaAs single crystal growth apparatus was prepared which had such a structure that the increased-diameter portion was constituted of an upper region and a lower region, the upper region was separated from the crucible holding base, and the lower region was in contact with the crucible holding base. The value of S(A2)/(S(A1)+S(A2)) represented by the above Formula I in the increased-diameter portion of the crucible was 0.1. Except for this, the GaAs single crystal substrate of sample 202 was obtained in the same manner as in sample 12. The crystal plane of the main surface of the GaAs single crystal substrate of sample 202 was a plane having an off angle of 6° with respect to the (100) plane in the [011] direction. Further, surface roughness Sa of the main surface of the GaAs single crystal substrate as measured by the above-described measurement method was 0.15 nm.

### <Samples 21 to 23, Sample 25, and Sample 203>

In preparation step S10, each of GaAs single crystal substrates of samples 21 to 23, sample 25, and sample 203 was obtained in the same manner as in sample 202 except that a GaAs single crystal growth apparatus having a below-described structure of an increased-diameter portion was prepared. In the GaAs single crystal growth apparatus used when producing the GaAs single crystal substrate of sample 21, the value of S(A2)/(S(A1)+S(A2)) represented by the above Formula I in the increased-diameter portion of the crucible was 0.2. In the GaAs single crystal growth apparatus used when producing the GaAs single crystal substrate of sample 22, the value of S(A2)/(S(A1)+S(A2)) represented by the above Formula I in the increased-diameter portion of the crucible was 0.3 In the GaAs single crystal growth apparatus used when producing the GaAs single crystal substrate of sample 23, the value of S(A2)/(S(A1)+S(A2)) represented by the above Formula I in the increased-diameter portion of the crucible was 0.4. In the GaAs single crystal growth apparatus used when producing the GaAs single crystal substrate of sample 25, the value of S(A2)/(S(A1)+S(A2)) represented by the above Formula 1 in the increased-diameter portion of the crucible was 0.6. In the GaAs single crystal growth apparatus used when producing the GaAs single crystal substrate of sample 203, the value of S(A2)/(S(A1)+S(A2)) represented by the above Formula I in the increased-diameter portion of the crucible was 0.8

### <Sample 24>

The GaAs single crystal substrate of sample 12 described above was obtained as the GaAs single crystal substrate of sample 24.

### <Evaluation on Properties>

The above-described measurement method or calculation method was performed onto each of the GaAs single crystal substrates of samples 21 to 25 and samples 201 to 203 so as to determine the atomic concentration of the silicon, the carrier concentration, the second carrier concentration, the atomic concentration of the boron, the average value of the dislocation density, and the dislocation-free ratio in each sample. The results are shown in Table 2. It should be noted that Table 2 also shows the off angle of the main surface of the GaAs single crystal substrate of each sample, the structure of the increased-diameter portion (presence or absence of the upper region and the lower region), the value of S(A2)/(S(A1)+S(A2)) represented by the above Formula I, and the like.

### <Device Yield>

The device yield (%) of each of these samples was determined by applying the same method as the method of determining the device yield in the first example to each of the GaAs single crystal substrates of samples 21 to 25 and samples 201 to 203. The results are shown in Table 2. It should be noted that in Table 2, as with Table 1, a sample having a device yield of 90% or more was determined to be A, a sample having a device yield of 80% or more and less than 90% was determined to be B, and a sample having a device yield of less than 80% was determined to be C.

TABLE 2

| | | | | Second | | |
|---|---|---|---|---|---|---|
| | Off | Si | Carrier | Carrier | B | Dislocation |
| | Angle | Concentration | Concentration | Concentration | Concentration | Density |
| | (°) | (cm⁻³) | (cm⁻³) | (*) | (cm⁻³) | (cm⁻²) |
| Sample 201 | 6 | 2.10 × 10¹⁸ | 1.59 × 10¹⁸ | 1.23 × 10⁻² | 2.70 × 10¹⁸ | 164 |
| Sample 202 | 6 | 2.10 × 10¹⁸ | 1.59 × 10¹⁸ | 1.85 × 10⁻² | 2.70 × 10¹⁸ | 31.1 |
| Sample 21 | 6 | 2.10 × 10¹⁸ | 1.61 × 10¹⁸ | 6.21 × 10⁻² | 2.80 × 10¹⁸ | 3.67 |
| Sample 22 | 6 | 2.10 × 10¹⁸ | 1.60 × 10¹⁸ | 1.33 × 10⁻² | 2.75 × 10¹⁸ | 0.752 |
| Sample 23 | 6 | 2.10 × 10¹⁸ | 1.60 × 10¹⁸ | 2.04 × 10⁻² | 2.70 × 10¹⁸ | 0.443 |
| Sample 24 | 6 | 2.10 × 10¹⁸ | 1.60 × 10¹⁸ | 1.22 × 10⁻² | 2.75 × 10¹⁸ | 0.286 |
| Sample 25 | 6 | 2.00 × 10¹⁸ | 1.59 × 10¹⁸ | 2.46 × 10⁻² | 2.90 × 10¹⁸ | 0.625 |
| Sample 203 | 6 | 2.10 × 10¹⁸ | 1.60 × 10¹⁸ | 1.84 × 10⁻² | 2.75 × 10¹⁸ | 19.5 |

| | | | | Structure of | | |
|---|---|---|---|---|---|---|
| | Dislocation- | Device | | Increased- | S(A2)/ | |
| | Free Ratio | Yield | Solidification | Diameter | (S(A1) + | |
| | (%) | (%) | Ratio | Portion | S(A2)) | Determination |
| Sample 201 | 70.68 | 20.5 | 0.27 | Only Lower | 1 * | C |
| | | | | Region | | |
| Sample 202 | 81.07 | 60.1 | 0.27 | Upper Region/ | 0.1 | C |
| | | | | Lower Region | | |
| Sample 21 | 98.04 | 89.9 | 0.27 | Upper Region/ | 0.2 | B |
| | | | | Lower Region | | |
| Sample 22 | 99.32 | 90.1 | 0.27 | Upper Region/ | 0.3 | A |
| | | | | Lower Region | | |
| Sample 23 | 99.64 | 91.3 | 0.27 | Upper Region/ | 0.4 | A |
| | | | | Lower Region | | |
| Sample 24 | 99.84 | 92.1 | 0.27 | Upper Region/ | 0.5 | A |
| | | | | Lower Region | | |
| Sample 25 | 99.21 | 89.5 | 0.27 | Upper Region/ | 0.6 | B |
| | | | | Lower Region | | |
| Sample 203 | 82.52 | 72.6 | 0.27 | Upper Region/ | 0.8 | C |
| | | | | Lower Region | | |

* S(A2)/(S(A1) + S(A2)) of 1 means that the entire surface of the increased-diameter portion on the crucible holding base side is in contact with the crucible holding base.
(*) The second carrier concentration is calculated by “[max − min]/average” of the carrier concentrations measured in the Hall measurement samples obtained from four positions on the main surface.

### <Review>

In each of the GaAs single crystal substrates of samples 21 to 25, the off angle of the main surface was 60, the average value of the dislocation density of the main surface was 0 cm⁻² or more and 3.77 cm⁻² or less, and the dislocation-free ratio was 98.04% or more. Further, the atomic concentration of the silicon was 1.0×10¹⁸ cm⁻³ or more and 5.0×10¹⁹ cm⁻³ or less, and the carrier concentration was 0.8×10¹′ cm⁻³ or more and 4.0×10¹⁸ cm⁻³ or less. Further, the device yield of each of these GaAs single crystal substrates was 89.5% or more, which was determined to be A or B. On the other hand, in the GaAs single crystal substrate of sample 201, the off angle of the main surface was 6°, but the average value of the dislocation density of the surface was more than 3.77 cm⁻², and the dislocation-free ratio was less than 98.04%. Further, the GaAs single crystal substrate of sample 201 was produced by the GaAs single crystal production apparatus having such a structure that the entire surface of the increased-diameter portion is in contact with the crucible holding base. In this case, the device yield of the GaAs single crystal substrate of sample 201 was less than 80%, which was determined to be C. In each of the GaAs single crystal substrates of samples 202 and 203, the off angle of the main surface was 6°, but the average value of the dislocation density of the surface was more than 3.77 cm⁻², and the dislocation-free ratio was less than 98.04%. Further, each of the GaAs single crystal substrates of samples 202 and 203 did not satisfy the relation of 0.1<S(A2)/(S(A1)+S(A2))<0.8. In this case, the device yield in each of these GaAs single crystal substrates was less than 80%, which was determined to be C. In particular, regarding the GaAs single crystal substrate of sample 202, the lower region held by the crucible holding base was too small, and it was difficult to grow the GaAs single crystal in a state in which the crucible is stabilized, with the result that the growth of the GaAs single crystal was presumed to be adversely affected. Regarding the GaAs single crystal substrate of sample 203, the lower region held by the crucible holding base was too large, and the relation between q(A1) and q(A2) became q(A1)≥q(A2) or the like, with the result that the growth of the GaAs single crystal was presumed to be adversely affected.

Heretofore, the embodiments and examples of the present disclosure have been illustrated, but it has been initially expected to appropriately combine configurations of the embodiments and examples.

The embodiments and examples disclosed herein are illustrative and non-restrictive in any respect. The scope of the present invention is defined by the terms of the claims, rather than the embodiments and examples described above, and is intended to include any modifications within the scope and meaning equivalent to the terms of the claims.

### REFERENCE SIGNS LIST

S10 preparation step; S20 step of obtaining GaAs single crystal; S21 source material loading step; S22 source material melting step; S23 GaAs single crystal growth step; S30 step of obtaining GaAs single crystal substrate; 10 GaAs single crystal growth apparatus; 5 crucible; 51 seed crystal accommodation portion; 52 increased-diameter portion; 521 upper region; 522 lower region; 53 straight barrel portion; 6 crucible holding base; 7 heating element; 75 thermocouple; 8a seed crystal; 81 gallium arsenide single crystal (GaAs single crystal); 82 gallium arsenide melt (GaAs melt); 1 gallium arsenide single crystal substrate (GaAs single crystal substrate); 11 main surface; 11a rectangular piece; 21 electrode; G imaginary grid; O center; 100 gallium arsenide single crystal (GaAs single crystal); 110 circular surface.

1. A method of producing a gallium arsenide single crystal having a columnar shape, the method comprising growing the gallium arsenide single crystal from a seed crystal using a gallium arsenide single crystal production apparatus, wherein
a growth side surface of the seed crystal is a plane having an off angle of 4° or more and 20° or less with respect to a (100) plane of the gallium arsenide single crystal,
the gallium arsenide single crystal production apparatus includes a crucible having a portion having a cylindrical shape, a crucible holding base that holds the crucible, and a heating element that heats the crucible,
the crucible includes a seed crystal accommodation portion, an increased-diameter portion connected to the seed crystal accommodation portion, and a straight barrel portion connected to the increased-diameter portion on a side opposite to the seed crystal accommodation portion side,
the seed crystal accommodation portion has a cavity portion having a cylindrical shape, the cavity portion being opened on a side on which the seed crystal accommodation portion is connected to the increased-diameter portion, the cavity portion being provided with a bottom wall formed on a side opposite to the increased-diameter portion,
the increased-diameter portion has a truncated conical shape having a diameter that is increased upward in an axial direction of the crucible, and is connected to the seed crystal accommodation portion on a small-diameter side of the increased-diameter portion,
the straight barrel portion has a hollow cylindrical shape and is connected to a large-diameter side of the increased-diameter portion,
the crucible holding base holds the increased-diameter portion,
the increased-diameter portion is constituted of an upper region and a lower region,
the upper region is separated from the crucible holding base, and
the lower region is in contact with the crucible holding base.

2. The method of producing the gallium arsenide single crystal according to claim 1, wherein when a surface area of the upper region is defined as S(A1) and a surface area of the lower region is defined as S(A2), the increased-diameter portion satisfies the following Formula I:
$$0.2 \leq S ( A 2 ) / ( S ( A 1 ) + S ( A 2 ) ) \leq 0.6 . \qquad Formula I$$

3. The method of producing the gallium arsenide single crystal according to claim 1, wherein the upper region faces the crucible holding base in a direction perpendicular to a growth direction of the gallium arsenide single crystal.

4. The method of producing the gallium arsenide single crystal according to claim 1, wherein the crucible holding base is composed of a single material.

5. The method of producing the gallium arsenide single crystal according to claim 4, wherein the material is composed of quartz.

6. The method of producing the gallium arsenide single crystal according to claim 4, wherein the material is non-transparent.

7. A method of producing a gallium arsenide single crystal substrate having a main surface having a circular shape, the method comprising obtaining the gallium arsenide single crystal substrate by cutting the gallium arsenide single crystal obtained by the method of producing the gallium arsenide single crystal according to claim 1 into a disk shape and by processing the gallium arsenide single crystal.

8. A gallium arsenide single crystal substrate having a main surface having a circular shape, wherein
a diameter of the gallium arsenide single crystal substrate is 200 mm or more and 210 mm or less,
the main surface is a plane having an off angle of 4° or more and 20° or less with respect to a (100) plane of the gallium arsenide single crystal,
an off direction of the plane having the off angle is any one of a [01-1] direction, a [0-1-1] direction, a [0-11] direction, or a [011] direction,
an average value of a dislocation density of the main surface is 0 cm⁻² or more and 3.77 cm⁻² or less,
in an imaginary grid formed by laying out squares each having each side of 2 mm on the main surface such that a largest number of the squares are arranged side by side without overlapping with each other, a ratio of the number of squares in each of which no dislocation is present to a total number of the squares constituting the grid is 98.04% or more,
the gallium arsenide single crystal substrate includes silicon,
a concentration of the silicon is 1.0×10¹⁸ cm⁻³ or more and 5.0×10¹⁹ cm⁻³ or less, and
a carrier concentration of the gallium arsenide single crystal substrate is 0.8×10¹⁸ cm⁻³ or more and 4.0×10¹⁸ cm⁻³ or less.

9. The gallium arsenide single crystal substrate according to claim 8, wherein
the gallium arsenide single crystal substrate includes boron, and
a concentration of the boron is 1.0×10¹⁸ cm⁻³ or more and 1.0×10¹⁹ cm⁻³ or less.

10. A gallium arsenide single crystal having a columnar shape, wherein
a diameter of a circular surface that forms a surface of the gallium arsenide single crystal is 200 mm or more and 210 mm or less,
the circular surface is a plane having an off angle of 4° or more and 20° or less with respect to a (100) plane of the gallium arsenide single crystal,
an off direction of the plane having the off angle is any one of a [01-1] direction, a [0-1-1] direction, a [0-11] direction, or a [011] direction,
an average value of a dislocation density in the circular surface is 0 cm⁻² or more and 3.77 cm⁻² or less,
in an imaginary grid formed by laying out squares each having each side of 2 mm on the circular surface such that a largest number of the squares are arranged side by side without overlapping with each other, a ratio of the number of squares in each of which no dislocation is present to a total number of the squares constituting the grid is 98.04% or more,
the gallium arsenide single crystal includes silicon,
a concentration of the silicon is 1.0×10¹⁸ cm⁻³ or more and 5.0×10¹⁹ cm⁻³ or less, and
a carrier concentration of the gallium arsenide single crystal is 0.8×10¹⁸ cm⁻³ or more and 4.0×10¹⁸ cm⁻³ or less.

11. The gallium arsenide single crystal according to claim 10, wherein a length of the columnar shape in an axial direction of the columnar shape is 40 mm or more and 110 mm or less.

12. The gallium arsenide single crystal according to claim 10, wherein
a carrier concentration of the gallium arsenide single crystal at one end of the gallium arsenide single crystal is 0.8×10¹⁸ cm⁻³ or more and 1.5×10¹⁸ cm⁻³ or less, and
a carrier concentration of the gallium arsenide single crystal at the other end of the gallium arsenide single crystal is 1.5×10¹⁸ cm⁻³ or more and 3.5×10¹⁸ cm⁻³ or less.

13. (canceled)
